(19) United States
(12) Patent Application Publication
(10) Pub. No.: US 2010/0171087 A1
(43) Pub. Date: Jul. 8, 2010

(54) SEMICONDUCTOR DEVICE AND PROCESS FOR PRODUCING THE SAME

(75) Inventors: Kenzo Kurotsuchi, Kodaira (JP); Motoyasu Terao, Hinode (JP); Takahiro Morikawa, Hachioji (JP); Norikatsu Takaura, Tokyo (JP)

Correspondence Address: MATTINGLY & MALUR, P.C., 1800 DIAGONAL ROAD, SUITE 370, ALEXANDRIA, VA, 22314, US

(73) Assignee: RENESAS TECHNOLOGY CORP., Tokyo (JP)

(21) Appl. No.: 12/600,333

(22) PCT Filed: May 21, 2007
(86) PCT No.: PCT/JP2007/060340

§ 371 Date: Dec. 8, 2009

(51) Int. Cl. H01L 45/00; H01L 21/06

(52) U.S. Cl. 257/2; 438/102; 257/E45.001; 257/E21.068

(57) ABSTRACT

In a semiconductor device including a phase change memory element whose memory layer is formed of a phase change material of M (additive element)-Ge (germanium)-Sb (antimony)-Te (tellurium), both of high heat resistance and stable data retention property are achieved. The memory layer has a fine structure with a different composition ratio therein, and an average composition of M_{α}Ge_{X}Sb_{Y}Te_{Z} forming the memory layer satisfies the relations of 0≦α≦0.4, 0.04≦X≦0.4, 0≦Y≦0.3, 0.3≦Z≦0.6, and 0.03≦(α+Y).

### TECHNICAL FIELD

The present invention relates to a semiconductor device and a technique of producing the same, and more particularly, the present invention relates to a technique effectively applied to a semiconductor device having a phase change memory element including a phase change material.

### BACKGROUND ART

There are a phase change memory and a phase change optical disk as a recording technique using a physical property of a chalcogenide material, and a chalcogenide material containing Te (tellurium) is known as a material (phase change material) of a memory layer used for these recording techniques.

U.S. Pat. No. 5,254,382 (Patent Document 1) discloses an optical disk medium using, as the memory layer, a chalcogenide material represented by [(Ge_{y}Te_{1-y})ₐ(Sb_{z}Te_{1-z})₁₋ₐ]_{1-b}(In₁₋ₓTeₓ)_{b} (here, 0.4≦y≦0.6, 0.3≦z≦0.6, 0.4≦z≦0.6, 0.1≦a≦0.5, 0.01≦b≦0.3). In this chalcogenide material, In (indium) is added to Ge (germanium)-Sb (antimony)-Te in order to increase the stability of an amorphous state and improve the long-term data retention property while keeping characteristics of rapid crystallization.

Meanwhile, in U.S. Pat. No. 5,883,827 (Patent Document 2), a nonvolatile memory using a phase change material film (chalcogenide material film) is described in detail. The nonvolatile memory is a phase change memory to which memory information is written by the change of atomic arrangement of a phase change material film depending on Joule heat caused by the current flowing in the phase change material film itself and its cooling speed. In this phase change memory, the operating current is likely to be large because a temperature over 600° C. caused by Joule heat is applied to the phase change material film upon amorphization to temporarily melt the phase change material film, and a resistance value of the phase change material film changes by two to three orders of magnitude depending on its state.

Also, with respect to an electric phase change memory, a phase change memory using Ge₂Sb₂Te₅ as chalcogenide has been mainly studied, and for example, Japanese Patent Application Laid-Open Publication No. 2002-109797 (Patent Document 3) discloses a recording element using GeSbTe. Further, Japanese Patent Application Laid-Open Publication No. 2003-100991 (Patent Document 4) discloses a technique related to a memory using a chalcogenide material. Still further, IEEE International Electron Devices meeting, TECHNICAL DIGEST, 2001, pp. 803-806 (Non-Patent Document 1) describes that a phase change memory using a phase change film made of Ge₂Sb₂Te₅ can rewrite 10¹² times, and Nature Materials, Vol. 4, 2005, pp. 347-351 (Non-Patent Document 2) discloses a technique related to a phase change memory using a crystal-growth type material.

Patent Document 1: U.S. Pat. No. 5,254,382

Patent Document 2: U.S. Pat. No. 5,883,827

Patent Document 3: Japanese Patent Application Laid-Open Publication No. 2002-109797

Patent Document 4: Japanese Patent Application Laid-Open Publication No. 2003-100991

Non-Patent Document 1: IEEE International Electron Devices meeting, TECHNICAL DIGEST, 2001, pp. 803-806

Non-Patent Document 2: Nature Materials, Vol. 4, 2005, pp. 347-351

### DISCLOSURE OF THE INVENTION

### Problems to be Solved by the Invention

When a phase change material used for an optical disk is used for a memory layer of a nonvolatile memory mounted on a microcomputer (semiconductor device), the memory layer is required to have higher resistance against high temperature in manufacturing processes and use environment unlike that in the optical disk. Therefore, when a memory is configured with using a standard phase change material such as Ge₂Sb₂Te₅ for the memory layer, the following problem has to be solved for improving the reliability with respect to the heat resistance.

That is, it is the instability of the phase change material in an amorphous state. More specifically, the amorphous state is a metastable phase, and therefore, its crystallization is rapidly progressed in a high temperature environment. For example, although a microcomputer for motor vehicle control is required to have the resistance against the usage in a high temperature environment of about 140° C., since amorphous is changed into a crystalline state, that is, a low resistance state in several hours when Ge₂Sb₂Te₅ is used for the memory layer, the data retention property is insufficient in such a high temperature environment, and therefore, the recording layer is not suitable for the usage in such a high temperature environment.

Also, since solder attachment and press bonding are performed to a memory-embedded microcomputer in a process of mounting a microcomputer chip on a wiring board or the like, a memory element formed on the chip is exposed to a high temperature environment. In the case of the microcomputer, the chip mounting is generally performed after recording a program in a memory unit. However, in such a memory that data is erased in a high temperature environment of the mounting process, data has to be written after the mounting, and therefore, a process different from a normal one has to be employed. For example, heat load of 260° C. for several minutes is applied in the solder attachment process and heat load of 180° C. for several hours is applied in the press bonding process, and therefore, it is required to guarantee a data retention property in a higher temperature environment than an operating temperature even for a short time. Therefore, a nonvolatile memory for a microcomputer needs to have a data retention property capable of withstanding such a heat load in the manufacturing process, and a heat resistance much higher than that of the optical disk is required.

As described above, a nonvolatile memory using a phase change material has the problem to be solved, and more particularly, since a resistance value in high temperature is a problem specific to a memory using an electrical chalcogenide material, it is not considered for a chalcogenide material for an optical disk (optical recording medium).

A preferred aim of the present invention is to provide a technique for achieving both the high heat resistance and the stable data retention property in a semiconductor device having a phase change memory element whose memory layer is formed of an M (additive element)-Ge (germanium)-Sb (antimony)-Te (tellurium) film. Note that the additive element can be at least one element selected from a group of, for example, In (indium), Ga (gallium), Al (aluminum), Zn (zinc), Cd (cadmium), Pb (lead), Si (silicon), V (vanadium), Nb (niobium), Ta (tantalum), Cr (chromium), Mo (molybdenum), W (tungsten), Ti (titanium), Fe (iron), Co (cobalt), Ni (nickel), Pt (platinum), Pd (palladium), Y (yttrium), and Eu (europium).

The above and other preferred aims and novel characteristics of the present invention will be apparent from the description of the present specification and the accompanying drawings.

### Means for Solving the Problems

Outlines of typical ones of the inventions disclosed in the present application will be briefly described as follows.

In a semiconductor device according to the present invention, the additive element or a compound of the additive element is precipitated in the memory layer formed of the M-Ge—Sb—Te film.

### EFFECTS OF THE INVENTION

Effects obtained by typical ones of the inventions disclosed in the present application will be briefly described as follows.

Since crystal growth is suppressed by the additive element or the compound of the additive element precipitated in the memory layer, the phase change memory element capable of achieving both the high heat resistance and the stable data retention property can be realized.

### BRIEF DESCRIPTIONS OF THE DRAWINGS

FIG. 1 is a cross-sectional view of a principal part of a phase change memory element according to an embodiment of the present invention;

FIG. 2 is a cross-sectional view of a principal part of a semiconductor device according to the embodiment of the present invention;

FIG. 3 is an explanatory diagram schematically illustrating a first state of a memory layer in a vicinity of a bottom electrode contact illustrated in FIG. 1;

FIG. 4 is an explanatory diagram schematically illustrating a second state of the memory layer in the vicinity of the bottom electrode contact illustrated in FIG. 1;

FIG. 5 is an explanatory diagram schematically illustrating a third state of the memory layer in the vicinity of the bottom electrode contact illustrated in FIG. 1;

FIG. 6 is an explanatory diagram schematically illustrating a fourth state of the memory layer in the vicinity of the bottom electrode contact illustrated in FIG. 1;

FIG. 7 is an explanatory diagram schematically illustrating a fifth state of the memory layer in the vicinity of the bottom electrode contact illustrated in FIG. 1;

FIG. 8 is an explanatory diagram schematically illustrating a sixth state of the memory layer in the vicinity of the bottom electrode contact illustrated in FIG. 1;

FIG. 9 is an explanatory diagram illustrating a relation between an In concentration of an In—Ge—Te—Sb phase change material and a crystallization temperature of the same;

FIG. 10 is a circuit diagram illustrating a memory cell array of the semiconductor device according to the embodiment of the present invention and peripheral circuits of the same;

FIG. 11 is a layout diagram illustrating the memory cell array of the semiconductor device according to the embodiment of the present invention and the peripheral circuits of the same;

FIG. 12 is an I-V characteristic diagram of the phase change memory element according to the embodiment of the present invention;

FIG. 13 is a waveform diagram explaining a reading operation from the phase change memory element according to the embodiment of the present invention;

FIG. 14 is a waveform diagram explaining a writing operation to the phase change memory element according to the embodiment of the present invention;

FIG. 15 is a cross-sectional view of the principal part illustrating a process for producing the semiconductor device according to the embodiment of the present invention;

FIG. 16 is a cross-sectional view of the principal part illustrating the process for producing the semiconductor device continued from FIG. 15;

FIG. 17 is a cross-sectional view of the principal part illustrating the process for producing the semiconductor device continued from FIG. 16;

FIG. 18 is a cross-sectional view of the principal part illustrating the process for producing the semiconductor device continued from FIG. 17;

FIG. 19 is a cross-sectional view of the principal part illustrating the process for producing the semiconductor device continued from FIG. 18;

FIG. 20 is a cross-sectional view of the principal part illustrating the process for producing the semiconductor device continued from FIG. 19;

FIG. 21 is a cross-sectional view of the principal part illustrating the process for producing the semiconductor device continued from FIG. 20;

FIG. 22 is a cross-sectional view of the principal part illustrating the process for producing the semiconductor device continued from FIG. 21;

FIG. 23 is a cross-sectional view of the principal part illustrating the process for producing the semiconductor device continued from FIG. 22;

FIG. 24 is a cross-sectional view of the principal part illustrating the process for producing the semiconductor device continued from FIG. 23;

FIG. 25 is an explanatory diagram schematically illustrating a structure of a resistor element;

FIG. 26 shows a result of a long-term EDX measurement for the resistor element after the phase change memory element according to the embodiment of the present invention has been rewritten multiple times; and

FIG. 27 is an explanatory diagram schematically illustrating the result of FIG. 26.

### BEST MODE FOR CARRYING OUT THE INVENTION

Hereinafter, an embodiment of the present invention will be described in detail with reference to the accompanying drawings. Note that components having the same function are denoted by the same reference symbols throughout the drawings for describing the embodiment, and the repetitive description thereof will be omitted. Also, in the present application, a contact of conductive layers includes not only a direct contact but also a contact made with interposing a layer or a region such as an insulator or a semiconductor which is so thin that current can flow therethrough.

A semiconductor device according to the embodiment of the present invention includes a phase change memory element (nonvolatile memory element) having a structure in which a resistor element including a phase change material (memory layer) and a MIS (Metal Insulator Semiconductor) transistor are connected in series. A main feature of the present invention is the phase change material (memory layer) employed for the phase change memory element. Accordingly, in the present specification, the phase change memory element will be described first, and then, the phase change material according to the present invention will be described. Next, a configuration of a memory cell array and an operation of the same will be described as one example of employing the phase change memory element. Next, the memory cell array including the phase change memory element and a process for producing the same will be described.

(Phase Change Memory Element)

First, a phase change memory element employing a phase change material will be described. For improving data retention property of the phase change memory element in a high temperature state, the inventors have studied about additions of various elements into a Ge—Sb—Te based chalcogenide material which is the phase change material. The additive element is at least one element selected from a group of In, Ga, Al, Zn, Cd, Pb, Si, V, Nb, Ta, Cr, Mo, W, Ti, Fe, Co, Ni, Pt, Pd, Y, and Eu.

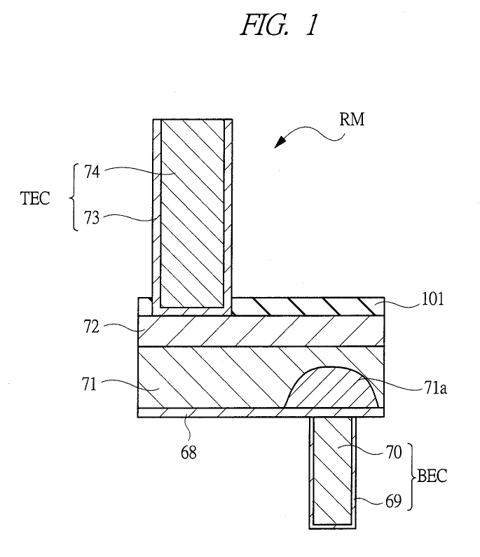

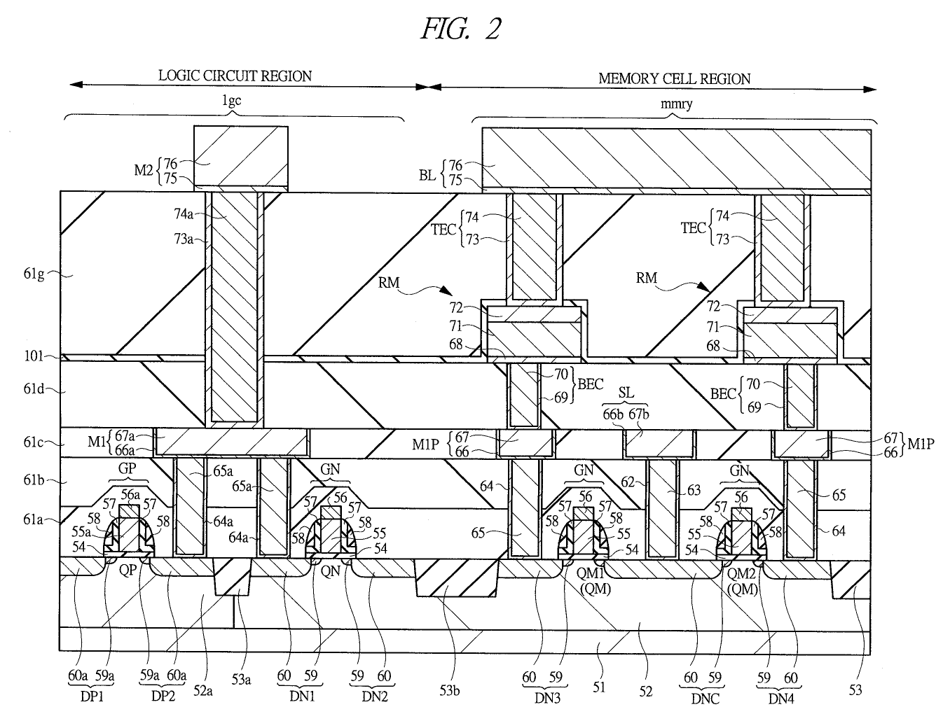

FIG. 1 is a cross-sectional view of a principal part of the phase change memory element and illustrates a resistor element configuring the phase change memory element. Also, FIG. 2 is a cross-sectional view of a principal part of a semiconductor device including the phase change memory element. Note that a detailed description about the semiconductor device illustrated in FIG. 2 will be made later.

As illustrated in FIG. 1, a memory layer 71 is sandwiched between paired electrodes (upper electrode layer 72 and bottom electrode contact BEC). The bottom electrode contact BEC is configured with a plug including a main conductive film 70 made of, for example, W (tungsten) or the like and a conductive barrier film 69 made of Ti (titanium)/TiN (titanium nitride) or the like. On the bottom electrode contact BEC, the memory layer 71 is formed via an interface layer 68 made of, for example, a Ta₂O₅ (tantalum oxide) film, a Cr₂O₃ (chromium oxide) film, or the like. The memory layer 71 is formed of a phase change material film almost uniformly containing, for example, In—Ge—Sb—Te in which In is added to a Ge—Sb—Te based chalcogenide material. On the memory layer 71, an upper electrode layer 72 made of a W film or the like is formed. The memory layer 71 is sandwiched between a pair of electrodes of the upper electrode layer 72 and the bottom electrode contact BEC to configure a resistor element RM.

As illustrated in FIG. 2, below the resistor element RM, a MIS transistor QM for a memory cell electrically connected to the bottom electrode contact BEC via a plug formed of a conductive barrier film 64 and a main conductive film 65 is formed. Semiconductor regions (source and drain regions) DN3 and DN4 of the MIS transistor QM are electrically connected to the plug formed of the conductive barrier film 64 and the main conductive film 65. Also, on the upper electrode layer 72, a plug TEC formed of a conductive barrier film 73 and a main conductive film 74 similar to the bottom electrode contact (plug) BEC is formed, and above the resistor element RM, a bit line BL electrically connected to the upper electrode layer 72 via the plug TEC is formed.

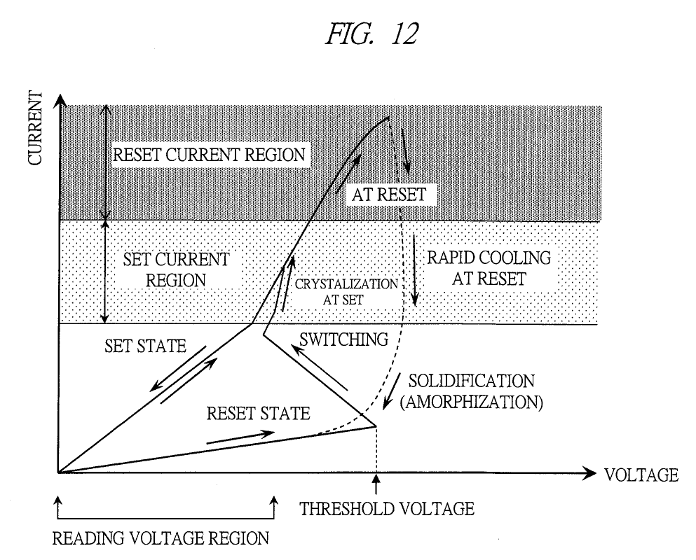

As illustrated in FIG. 1, in the resistor element RM of the phase change memory element, a shape of the bottom electrode contact BEC and a shape of the upper electrode layer 72 are different. In such a case, the temperature on the side of the bottom electrode contact BEC having a small contact area with the memory layer 71 formed of the phase change material film is likely to increase. That is, while the memory layer 71 on the upper electrode layer 72 side having a large contact area is not melted at a reset or is re-crystallized during cooling even if it is melted, an amorphous region 71a is provided in the memory layer 71 in a vicinity of the bottom electrode contact BEC having the small contact area. Note that, although described later with reference to FIG. 12, after the reset, the melting of the phase change material (memory layer 71) is partially started by the heat (Joule heat), and its conductivity is gradually lowered to be a high resistance state.

When the bottom electrode contact BEC has a column shape or a tube shape, current flows in from an upper and outer portion of the bottom electrode contact BEC, and therefore, current density is increased in an outer edge portion of a region where the bottom electrode contact BEC having the column shape or the tube shape is contacted to the memory layer 71. Here, the shortest distance between the bottom electrode contact BEC and a crystallized region closest thereto differs depending on how large and how long current is supplied at the reset. For example, when a size of the resistor element RM is small, the current is reduced, so that a distance (closest path) between the bottom electrode contact BEC and the crystallized region closest to a bottom portion of the amorphous region 71a becomes shorter than a distance between the bottom electrode contact BEC and the upper electrode layer 72 (or a distance between the bottom electrode contact BEC and the crystallized region on an upper portion of the amorphous region 71a) along a thickness direction of the memory layer 71. Therefore, there is a high possibility that large current flows along the closest path at a set. Note that, although described later with reference to FIG. 12, after the set, the phase change material (memory layer 71) becomes the low resistance state.

As described above, in the phase change memory element according to the present embodiment, the memory layer 71 is phase-changed to be a high resistance state or a low resistance state, and these states are memorized therein.

Incidentally, since the closest path is likely to be unstable due to the variation or failure in the processes for the memory layer 71, an error such as characteristic variation among the resistor elements RM or decrease of the number of rewritable times probably occurs.

In addition, there is a possibility that the atomic arrangement of the In—Ge—Sb—Te film which forms the memory layer 71 is changed in the high temperature state, that is, the heat-applied state, and this causes further resistance increase of the memory layer 71, so that higher voltage is possibly required at a next set operation. More specifically, when the amorphous region 71a is in an amorphous state, if the change of the atomic arrangement is caused in the whole crystallized region at high temperature and the further resistance increase occurs, the next set operation becomes difficult to be performed in some cases.

Also, since strong electric field is applied to the resistor element RM having the structure in which the memory layer 71 is sandwiched by the bottom electrode contact BEC and the upper electrode layer 72 which are paired electrodes, if ion or easily ionized element or component exists in the memory layer 71 between the paired electrodes, there is a possibility that they are moved due to the electric field. That is, in FIG. 1, since a crystallized region from an initial period has a low resistance, when the composition along the thickness direction of the memory layer 71 is uniform, the potential slope between the outer edge portion of the bottom electrode contact BEC and the crystallized region from an initial period becomes largest at the set, so that the set operation accompanied with the impact ionization is started. At this time, the movement of the positive ion also occurs more frequently, and segregation or disarray in structure occurs at high temperature, and this causes the resistance change toward the high resistance side. Note that, since high voltage is generally applied to the upper electrode layer 72 side on the basis of the bottom electrode contact BEC side at the set/reset operation, the positive ion is easy to move toward the bottom electrode contact BEC side.

Further, there is a possibility that an element, more particularly, a metal element which forms the paired electrodes diffuses in the memory layer 71 due to high temperature caused by current, and further, it is ionized and moved due to the potential slope. More particularly, since the temperature is increased in the outer edge portion on the side in contact with the bottom electrode contact BEC having the column shape or in the vicinity at which the bottom electrode contact BEC having the tube shape is in contact with the memory layer 71 because of current concentration, the element forming the paired electrodes is likely to diffuse in the memory layer 71.

Therefore, when the memory layer 71 of the phase change memory element is formed of, for example, an In—Ge—Sb—Te film, by forming the interface layer 68 formed of a Ta₂O₅ film, a Cr₂O₃ film, or the like between the memory layer 71 and the bottom electrode contact BEC, heat resistance can be improved and a reset (amorphization) current can be reduced. However, on the other hand, the further resistance increase supposedly caused by the change of the atomic arrangement is caused in the high temperature state, so that high voltage is required at the next set operation in some cases.

(Phase Change Material)

The phase change memory element according to the present embodiment includes the resistor element RM having: the upper electrode layer 72; the memory layer 71 made of a phase change material; and the bottom electrode contact BEC. The memory layer 71 in the resistor element RM becomes either an electrically high resistance state or an electrically low resistance state, and information is memorized by maintaining the state.

The phase change material forming the memory layer 71 having the main feature of the present invention is not uniform and has a fine composition modulation at least in the low resistance state. Hereinafter, although the case where the phase change material (memory layer 71) is not uniform and has the fine composition modulation in the low resistance state will be described, it is preferable that the phase change material has the same fine composition modulation also in the high resistance state. Note that “fine” in the present application means that a crystal grain size is smaller than a thickness of the phase change material (memory layer 71), and for example, the crystal grain is so small that it cannot be observed by the cross-sectional TEM (transmission electron microscope).

One example of the composition modulations is a fine composition modulation caused by the difference in compositions between the crystal grain and an inter-grain portion in a case of polycrystal. Also, another example is a fine composition modulation caused by Spinodal decomposition from an amorphous state. Still another example is a fine composition modulation caused by pressing ion, more particularly, metal ion into a space of the atomic arrangement by the electric field. In this case, in addition to a fine composition modulation in an in-plane direction, a composition change is caused also in a film thickness direction. Such a composition change is also preferable. There are the cases where the phase change material is wholly amorphous, partially fine crystal, and wholly fine crystal.

It has been considered that single phase is better for a crystal state of the phase change material until now. This is because a distance of the atomic movement is desired to be as small as possible for a rapid phase change. However, in the case of the phase change memory, extremely high heat resistance is required depending on usage, and the achievement of the heat resistance is difficult in an amorphous state where a single phase crystal is rapidly generated.

On the other hand, in an amorphous state where a fine crystal state is divided into two or more phases, a Spinodal-decomposed amorphous state is also included therein, but even if one phase of the two phases is crystallized, if the other phase is in an amorphous state, the high resistance state between electrodes is maintained. The amorphous state portion can be considered as a crystal grain boundary, but the number of atoms sandwiched between crystals is larger than that of a normal crystal grain boundary. Also, in a case of being divided into three phases, the high resistance state can be preferably maintained when two phases of them are crystals each having a different crystal shape and the rest phase left therebetween is in the amorphous state.

High temperature is required for crystallizing the rest amorphous phase. However, this does not always mean that the rest amorphous phase itself has a high heat resistance. In other words, when the whole phase change material is the amorphous phase, the heat resistance is not always high. Therefore, it is considered that the crystallization becomes difficult due to the rest amorphous phase left so as to be sandwiched between the crystal phases.

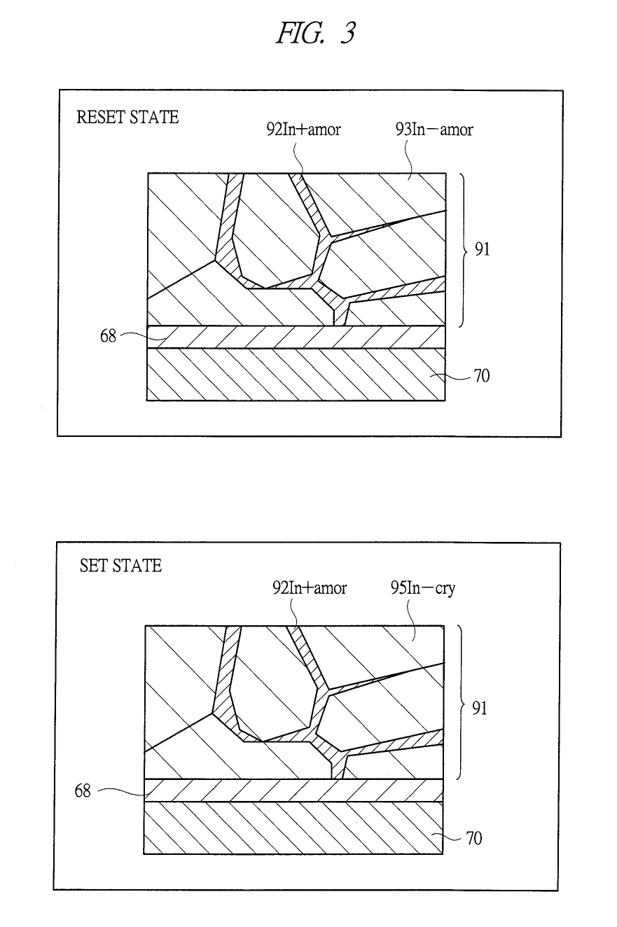

The fine crystal structure will be further described with reference to FIGS. 3 to 8. FIGS. 3 to 8 schematically illustrate the memory layer 71 in a vicinity of the bottom electrode contact (plug) BEC illustrated in FIG. 1.

Although a precise analysis of the fine crystal structure is difficult because it is so small as to be difficult to evaluate by general analysis means such as the cross-sectional TEM (transmission electron microscope) observation, it can be described by using the following models. For example, the case where the Ge—Sb—Te based chalcogenide material containing In as an additive element, that is, a phase change material whose component elements are In, Ge, Sb, and Te is used will be described. Note that the additive element is not limited to In, and at least one element selected from a group of Ga, Al, Zn, Cd, Pb, Si, V, Nb, Ta, Cr, Mo, W, Ti, Fe, Co, Ni, Pt, Pd, Y, and Eu may be added.

First, a first model will be described with reference to FIG. 3. Note that a resistance between a bit line and a source line of a memory cell is changed by the change of the crystallization ratio of a phase change region 91.

In the case of the reset state, that is, the high resistance state, the phase change region 91 is configured with: a region 92 which has a high In concentration as compared with an average composition of the In—Ge—Sb—Te forming the memory layer 71 and is amorphous (hereinafter, indicated by “In+amorphous”); and a region 93 which has a low In concentration as compared with the average composition of the memory layer 71 and is amorphous (hereinafter, indicated by “In−amorphous”). In other words, the memory layer 71 has a region in which In being the additive element or InTe being a compound of the additive element is precipitated like, for example, the In+amorphous 92. Also, the precipitated In or InTe being the compound of the additive element is amorphous, and amorphous regions each having a different composition such as the In+amorphous 92 and the In−amorphous 93 are mixed in the memory layer 71 in the high resistance state.

Therefore, with respect to the heat resistance, even if crystal nuclei are formed within the In+amorphous 92 in the reset state to grow into crystals, the crystals impact to the In−amorphous 93, so that the crystal growth is prevented. Since compositions of the In+amorphous 92 and the In−amorphous 93 are different from each other, their lattice constants are different from each other, and they do not become the same crystal. Therefore, their crystal sizes are minute, so that they do not affect the resistance between the bit line and the source line, that is, the high resistance is maintained. Note that, when the crystal grain size is small, since a volume of the crystal is small as compared with its surface area, a generated crystal embryo is sometimes returned back to amorphous by thermal vibration.

In the case of the set state, that is, the low resistance state, the phase change region 91 is configured with: the In+amorphous 92; and a region 95 which has a low In concentration as compared with the average composition of the In—Ge—Sb—Te forming the memory layer 71 and is a crystal phase (hereinafter, indicated by “In−crystal”). In other words, the memory layer 71 has a region in which In being the additive element or InTe being the compound of the additive element is precipitated like, for example, the In+amorphous 92. Also, the precipitated In or InTe being the compound of the additive element is amorphous, and amorphous and crystal such as the In+amorphous 92 and the In−crystal 95 are mixed in the memory layer 71 in the low resistance state. The In+amorphous 92 is precipitated among the In−crystals 95. The In−crystal 95 has a composition close to that of the Ge—Sb—Te based chalcogenide material being the original material, and it is considered that the In−crystal 95 is In—Ge—Sb—Te having a composition close to that of Ge₂Sb₂Te₅ as compared with, for example, the In+amorphous 92.

A thickness of the In+amorphous 92 is small as compared with a grain size of the In−crystal 95. Also, the grain size of the In−crystal 95 is smaller than Ge₂Sb₂Te₅. In other words, the grain size of the In−crystal 95 of the memory layer 71 is smaller than the shortest direction between the paired electrodes (upper electrode layer 72 and bottom electrode contact BEC).

Therefore, by lengthening a set pulse width, time margin and temperature for thermally diffusing excessive In from the In−crystal 95 to the In+amorphous 92 can be provided. The pulse width at this time is, for example, 1 microsecond or longer. Also, by shortening a reset pulse width, thermal diffusion from the In+amorphous 92 to the In−crystal 95 in meltdown is suppressed, so that composition nonuniformity in the memory layer 71 can be maintained. The pulse width at this time is, for example, less than 50 nanoseconds.

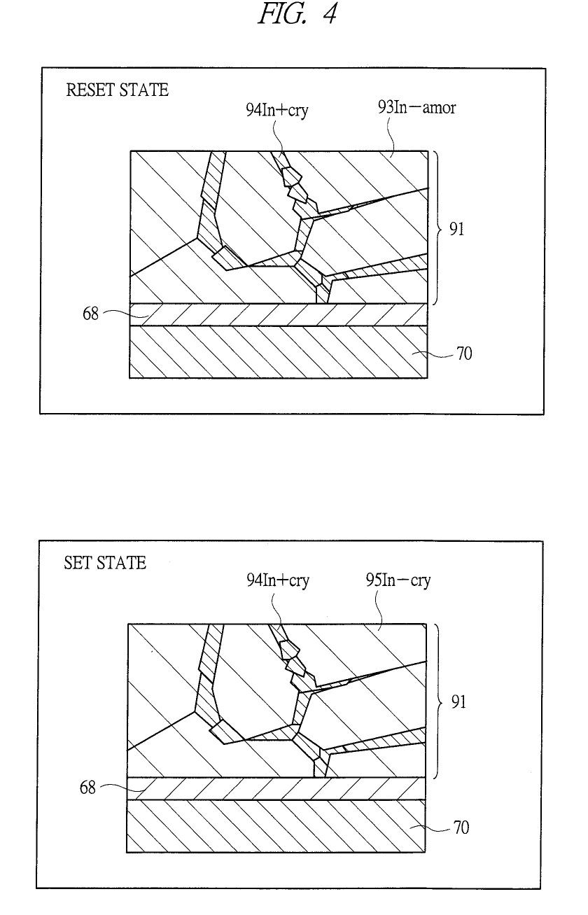

Next, a second model will be described with reference to FIG. 4. In the reset state, a region 94 which has a high In concentration as compared with the average composition of the In—Ge—Sb—Te forming the memory layer 71 and is a crystal phase (hereinafter, indicated by “In+crystal”) exits in the periphery of the In−amorphous 93. Also in this case, the heat resistance of the reset state is similarly secured. It is preferable that a crystal grain size of the In+crystal 94 is as fine as, for example, 20 nm or smaller for the reduction of the variation between elements.

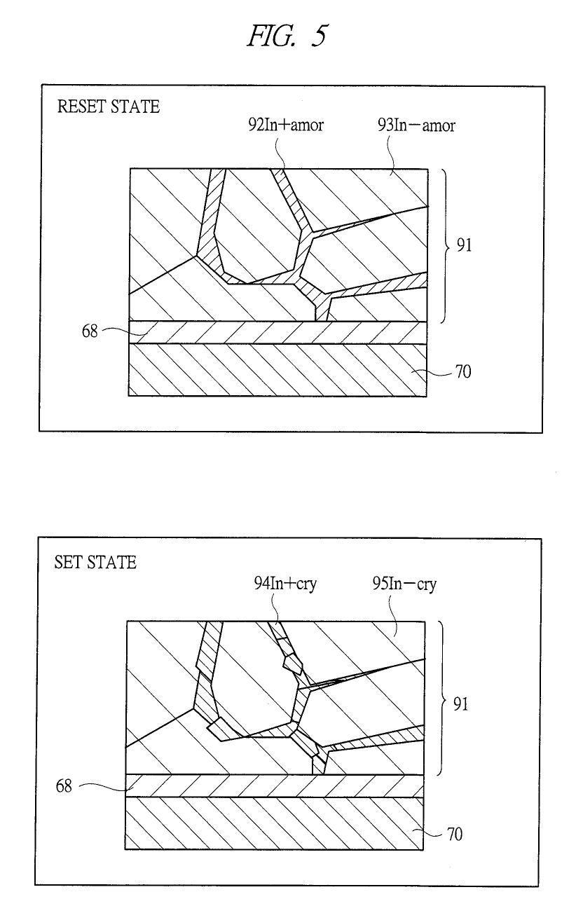

Next, a third model will be described with reference to FIG. 5. In this model, the region having the high In concentration is amorphous (In+amorphous 92) in the reset state, and the region having the high In concentration is crystal (In+crystal 94) in the set state.

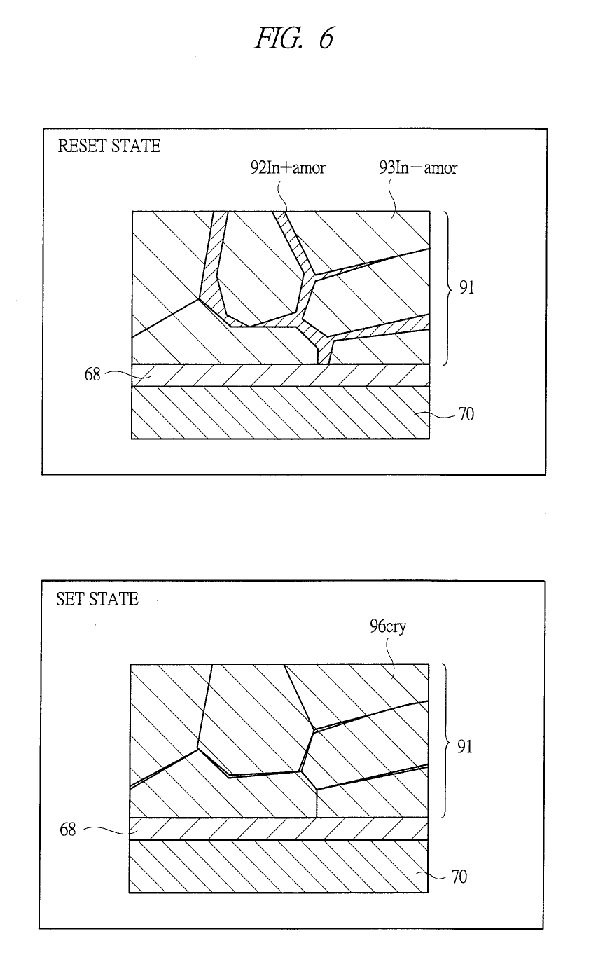

Next, a fourth model will be described with reference to FIG. 6. In the reset state, the phase change region 91 is configured with the In−amorphous 93 and the In+amorphous 92. The suppression of the crystallization of the In−amorphous 93 by the In+amorphous 92 is the same as the first model. A feature of this model is that a plurality of crystals 96 are formed and the In concentration in the vicinity of the grain boundary is high in the set state. In the grain boundary between crystals, crystal lattice is generally disordered. Therefore, since thermodynamic energy of the whole of the memory layer 71 can be reduced more when impurities are positioned at the grain boundary which is originally energetically unstable than positioned at a mother phase of the crystal, the In concentration in the vicinity of the grain boundary having the crystal lattice disorder is high. For example, it has been verified by our extended X-ray absorption fine structure (EXAFS) measurement using synchrotron radiation that, when the additive element is Zn, Zn is introduced into a crystal lattice formed of the Ge—Sb—Te based chalcogenide material so as to displace Ge or Sb with Zn.

As described above, the first model to the fourth model are different in that the high In concentration region is either the crystal phase or the amorphous phase.

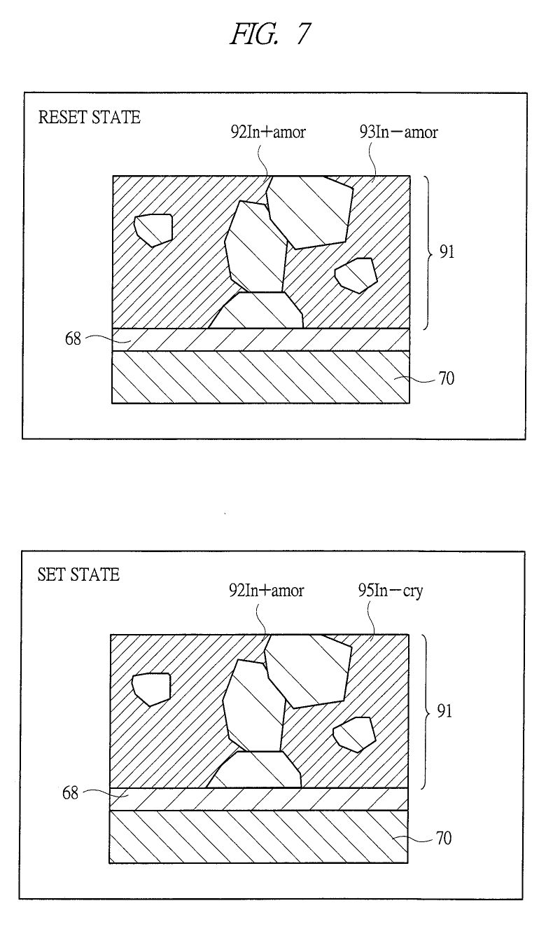

Next, a fifth model will be described with reference to FIG. 7. The fifth model is different from the first model in that volume fraction of the In+amorphous 92 occupied in the memory layer 71 is large in the set state. For example, the In+amorphous 92 occupies larger volume than the crystal 95.

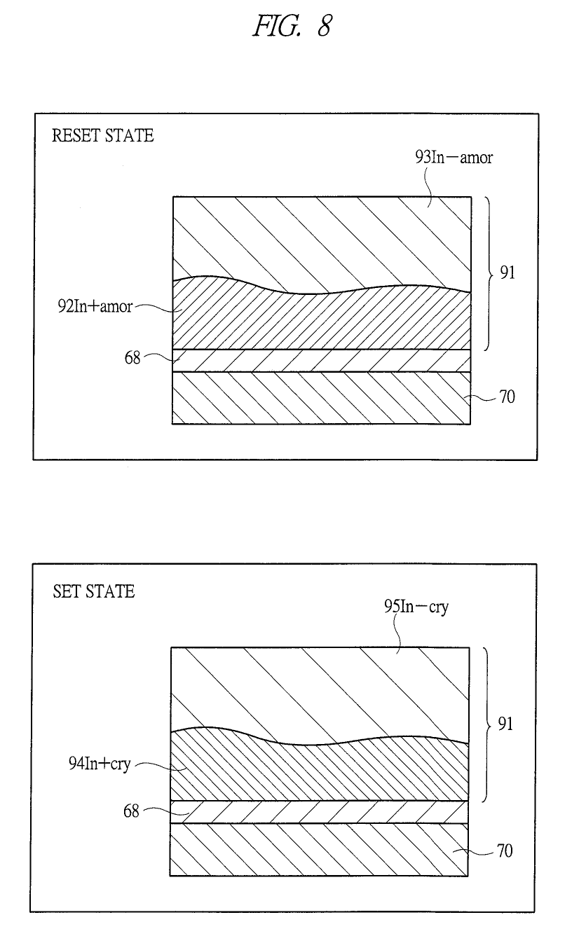

Next, a sixth model will be described with reference to FIG. 8. A feature of this model is that an In concentration changes in the current flow direction. Therefore, the concentration of In being the additive element in the memory layer 71 is higher on one electrode side of the paired electrodes (upper electrode layer 72 and bottom electrode contact BEC) than on the other electrode side. More specifically, a local difference of the In concentration is caused by the current flow and In has a positive electronegativity as compared with Te, and therefore, ion conduction occurs when the current flows, so that In moves to a cathode side, that is, to the bottom electrode contact BEC (main conductive film 70) being the cathode.

Therefore, even if the In−amorphous 93 is crystallized in the reset state, since the In+amorphous 92 having high resistance because it is amorphous is present between the bottom electrode contact BEC and the upper electrode layer TEC, the high electric resistance between the bottom electrode contact BEC and the upper electrode layer TEC is maintained.

FIG. 9 illustrates a relation between an In content percentage and a crystallization temperature of the phase change material made of In—Ge—Te—Sb. Note that the In content percentage corresponds to that in the average composition of In—Ge—Te—Sb.

As illustrated in FIG. 9, the crystallization temperature is increased by the addition of In. The crystallization temperature for the In content percentage (α) is, for example, about 180° C. for 3 atom %, 250° C. for 10.5 atom %, about 270° C. for 30 atom %, and about 250° C. for 40 atom %. In a phase change memory element using the memory layer 71 in which In being the additive element or its compound (In compound) is precipitated so that a crystallization temperature is in a high range as described above, the crystallization is difficult to occur even in the high temperature like the use environment (about 140° C.) of a microcomputer for motor vehicle control. More specifically, even if the memory layer 71 is exposed to the high temperature environment when it is in the high resistance state, since the crystallization is hard to occur in the memory layer 71, the memory layer 71 is not changed to be low resistance, so that information can be retained.

(Configuration of Memory Cell Array and Operation of the Same)

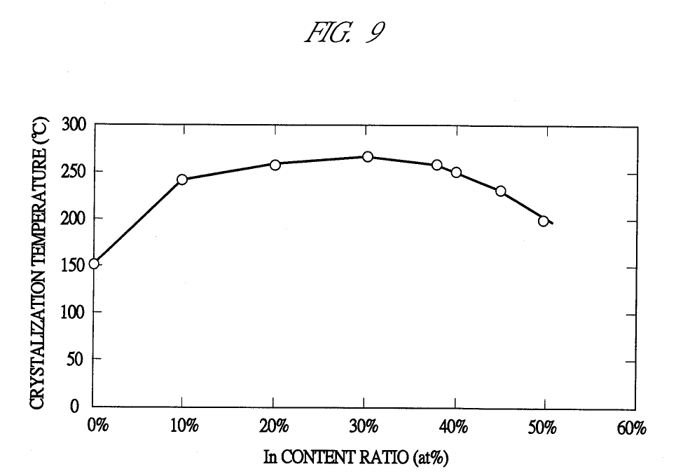

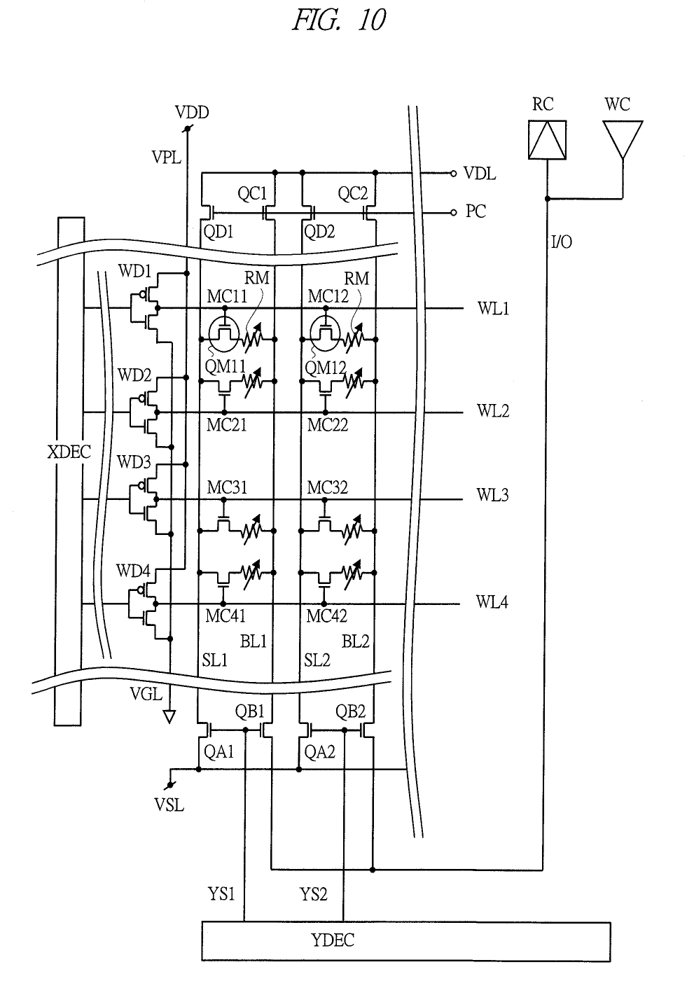

First, a memory cell array according to the present embodiment will be described. FIG. 10 is a circuit diagram illustrating the memory cell array according to the present embodiment and peripheral circuits of the same. Note that, for preventing complicate descriptions, a lot of word lines WL and bit lines BL generally provided are simplified, and only four word lines WL1 to WL4, two bit lines BL1 and BL2, and two source lines SL1 and SL2 are illustrated.

The memory cell array according to the present embodiment illustrated in FIG. 10 is an NOR-type configuration example, and since high speed reading can be performed, this is suitable for a storage memory of system program or the like. Therefore, the memory cell array is mainly used as a single memory or a memory embedded logic LSI such as a microcomputer.

Memory cells MC11 and MC12 are electrically connected to the word line WL1. Similarly, memory cells MC21 and MC22, MC31 and MC32, and MC41 and MC42 are connected to the word lines WL2, WL3, and WL4, respectively. Also, the memory cells MC11, MC21, MC31, and MC41 are connected to the bit line BL1 and the source line SL1. Similarly, the memory cells MC12, MC22, MC32, and MC42 are connected to the bit line BL2 and the source line SL2.

Each memory cell MC is configured with: one memory cell transistor QM formed of a MIS transistor; and one resistor element RM connected to the memory cell transistor in series. The word line WL is connected to a gate electrode of each memory cell transistor QM, and the bit line BL is connected to the resistor element RM. Also, in each memory cell transistor QM, the resistor element RM is connected to one end thereof (one of the source and drain regions) and the source line SL is connected to the other end thereof (the other of source and drain regions). Note that, as described above with reference to FIG. 1, the resistor element RM has a stacked structure of the bottom electrode contact BEC, the interface layer 68, the memory layer 71, and the upper electrode layer 72 in this order from below, and the memory layer 71 is made of a phase change material.

The word lines WL1 to WL4 are driven by word drivers WD1 to WD4, respectively. The signal from an X address decoder XDEC determines which word driver WD is to be selected.

Also, in FIG. 10, a symbol VPL indicates a power supply line to each word driver WD, a symbol Vdd indicates a power supply voltage of, for example, 1.5 V, and a symbol VGL indicates a potential pull-out line of each word driver WD. Note that the potential pull-out line VGL is fixed to ground voltage.

Further, a row decoder XDEC, a column decoder YDEC, a reading circuit RC, and a writing circuit WC which are required for the operation of the memory array are simultaneously illustrated. A feature of this configuration lies in that the source line is provided in parallel with the data line, and a pre-charge circuit for driving both of them to the same potential and a circuit for selectively driving a selected source line are arranged, whereby a current path is provided to only a selected cell which is positioned at an intersection of the selected word line and the selected source line.

The row decoder XDEC selects the word line WL in accordance with a row address. Also, the column decoder YDEC drives a column selection line YS in accordance with a column address. A column selection switch QA in accordance with the selected column selection line YS is conducted, whereby the selected memory cell MC is connected to the reading circuit RC or the writing circuit WC via a common data line I/O.

Here, QA1 and QA2 can be regarded as a first switch circuit for selecting one of the plurality of data lines (BL1 and BL2) and connecting the one to the common data line I/O. Also, QB1 and QB2 can be regarded as a second switch circuit for selecting one of the plurality of source lines (SL1 and SL2) and connecting the one to the source voltage supply line.

This memory array configuration has the following three features. The first one is that a plurality (here, m lines) of source lines SLr (r=1, 2, . . . ) in parallel with the bit line BL are arranged and sources of transistors QMr in a column direction are commonly connected to the source line SLr.

The second one is that a plurality (here, m pieces) of NMIS transistors QBr (r=1, 2, . . . ) are inserted between respective source lines SLr and a source voltage terminal VSL and these transistors are selected by the column decoder. FIG. 10 illustrates an example in which column select lines YSr corresponding to these gates are directly connected.

The third one is that a plurality of NMIS transistors QCr and QDr (r=1, 2, . . . ) for driving the corresponding bit line BL and source line SL to the pre-charge voltage VDL are arranged and a pre-charge enable signal PC is connected to the gates of these transistors. By such a configuration, a source line corresponding to a data line to be selected can be driven from among the plurality of bit lines BL and source lines SL driven to the pre-charge voltage VPC. More specifically, voltage difference can be applied to only a memory cell MC connected to the bit line and data line to be selected. Therefore, the current path can be provided for only the desired memory cell MC on the selected word line, and the reading signal can be generated to only the selected data line. Note that the pre-charge circuit can be understood as whole QC and QD, and QC1 and QD1 can be regarded as a component pre-charge circuit provided for each pair of BL1 and SL1.

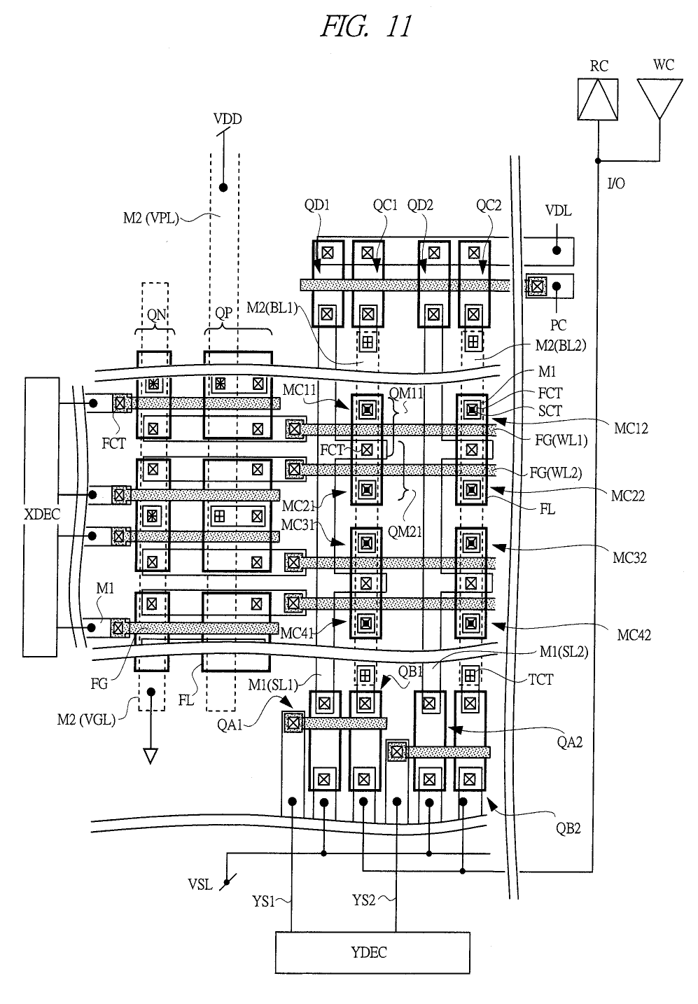

FIG. 11 is a layout diagram corresponding to the circuit of FIG. 10. In FIG. 11, a symbol FL indicates an active region of a MIS transistor, a symbol M1 indicates a first layer wire, a symbol M2 indicates a second layer wire, and a symbol FG indicates a gate electrode of a MIS transistor formed on a silicon substrate. A symbol FCT indicates a contact hole for connecting a semiconductor region (source and drain region) of a MIS transistor and the first layer wire M1, a symbol SCT indicates a contact hole for connecting the first layer wire M1 and the resistor element RM, a symbol TCT indicates a contact hole for connecting the first layer wire M1 and the second layer wire M2, and a symbol YS indicates the column selection line, respectively.

The resistor element RM of the memory cell MC is connected to the bit line BL (second layer wire M2) via the contact hole TCT between the plurality of memory cells MC each connected to the same bit line BL. Each of the word lines WL1 to WL4 is configured with the gate electrode FG formed of a stacked layer of a polycrystalline silicon film and a silicide (alloy of silicon and a high-melting-point metal) film or the like. Also, for example, the memory cell transistor QM11 of the memory cell MC11 and the memory cell transistor QM21 of the memory cell MC21 share a source region. The source region is electrically connected via the contact hole FCT to the first layer wire M1 configuring the source line SL1.

The bit lines BL1 and BL2 are connected to source regions of selecting transistors QB1 and QB2 arranged in a periphery portion of the memory cell array, respectively. These selecting transistors have a function of receiving a signal from the Y address decoder YDEC to select the bit line BL1 or BL2 assigned by the signal.

Next, a memory element according to the present embodiment in which states of the electric resistance value changed to high resistance and low resistance (high resistance state and low resistance state) by the phase change of the memory layer (phase change material) are memorized as binary information will be described. Note that, as described above with reference to FIGS. 1 and 2, the phase change memory element is configured with the resistor element RM and the MIS transistor QM, and the resistor element RM has a stacked structure of the bottom electrode contact BEC, the interface layer 68, the memory layer 71, and the upper electrode layer 72 in this order from below.

When memory information “0” is written, a reset pulse for heating the resistor element RM to a temperature higher than or equal to a melting point of the phase change material, and then, rapidly cooling the same is applied. At that time, the whole energy to be given is made small by shortening the reset pulse and the cooling time is set to be short (for example, about 1 ns), whereby the phase change material becomes an amorphous state with high resistance.

On the other hand, when memory information “1” is written, a set pulse for maintaining the resistor element RM at a temperature region lower than the melting point of the phase change material and equal to glass transition temperature or higher than the crystallization temperature is applied, whereby the phase change material becomes a polycrystalline state with low resistance. Although the time required for the crystallization differs depending on the composition of the phase change material, it is, for example, about 50 ns.

The temperature of the resistor element RM depends on Joule heat generated by the element itself and thermal diffusion to its circumference. FIG. 12 is an I-V characteristic diagram of the phase change memory element. In the memory element according to the present embodiment, the crystal state of the memory layer 71 is controlled by applying the current pulse having a value in accordance with the written information to the resistor element RM.

FIG. 12 schematically illustrates an operation principle of the resistor element RM using the phase change material, and it shows that the memory information “1” is written when a set current within a range illustrated in FIG. 12 is applied and the memory information “0” is written when a reset current larger than the set current is applied. Note that it is arbitrary which state is taken as “0” or “1”. Hereinafter, four writing operations will be described with reference to FIG. 12.

First, in a case of writing “1” to the resistor element RM whose initial state is “1”, when the set current is applied, the state is maintained because it goes back and forth between the initial state and a set region as following a low resistance curve of the set (crystal) state.

Second, in a case of writing “0” to the resistor element RM whose initial state is “1”, when the reset current is applied, the state reaches a reset state as following the low resistance curve of the set state. Next, since partial melting is started by Joule heat, the conductivity is gradually lowered. When the resistor element RM being liquid phase is rapidly cooled by turning off the pulse, the phase is changed to an amorphous state, and therefore, the state is returned back to the initial state as partially following a high resistance curve of the reset (amorphous) state. A curve illustrated by a dashed line in FIG. 12 is a virtual line based on the assumption that, though the reset pulse is already turned off, the current should be changed like this by the resistance value change if the application of voltage is continued.

Third, in a case of writing “1” to the resistor element RM whose initial state is “0”, when the set current is applied, the state is switched to the low resistance state when a terminal voltage of the element exceeds a threshold voltage. After the switching, the crystallization is advanced by Joule heat. When the current value reaches the set current, the crystallized region spreads to cause the phase change, so that the resistance value is further lowered, and therefore, the state is returned back to the initial state as following the low resistance curve. The reason why the slope of the current-voltage curve becomes gentle on the way is that the region switched to the low resistance state is turned off and only the resistance reduction by the crystallization remains.

Fourth, in a case of writing “0” to the resistor element RM whose initial state is “0”, there is almost no time for the crystallization after the above-described switching, and the state reaches the reset region as following the low resistance curve by the switching, so that it returned back to the initial state after melting, rapidly cooling, and solidification.

According to the above-described operation principle of the resistor element RM, in order to prevent the memory information from being destroyed at the reading, the operation has to be performed with controlling the voltage to not more than the threshold voltage. Actually, the threshold voltage depends also on a voltage application time and there is a tendency that the threshold voltage is lowered as the time becomes longer, and therefore, it is required to set the voltage so as not to exceed the threshold voltage within the reading time to prevent the switching to the low resistance state. Based on these principles, an operation for realizing the array configuration illustrated in FIG. 10 will be described below.

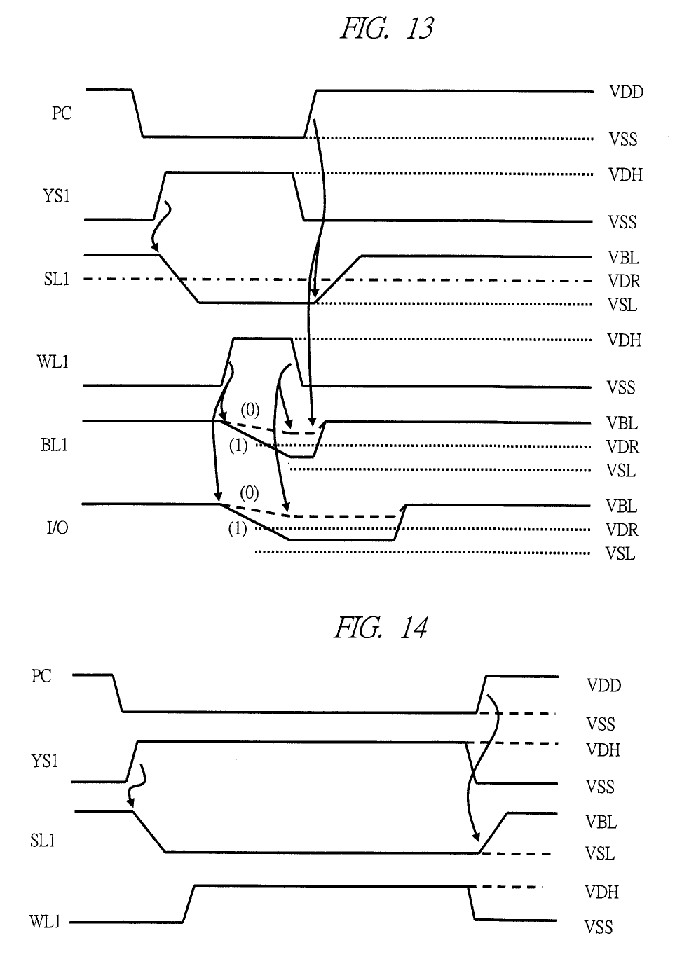

FIG. 13 illustrates waveforms explaining the reading operation from the phase change memory element according to the embodiment of the present invention. With reference to FIG. 13, the reading operation from the memory cell MC11 will be described. Note that FIG. 13 illustrates operation waveforms in a case of selecting the memory cell MC11 illustrated in FIG. 10.

First, in a stand-by state, the pre-charge enable signal PC is maintained at the power supply voltage VDD, and therefore, the bit line BL and the source line SL are maintained at the pre-charge voltage VBL by the selecting transistor QD. Here, the pre-charge voltage VBL has a value (for example, 1.0 V) fallen from the power supply voltage VDD by the threshold voltage Vth of the transistor. Also, at this time, the common data line I/O is also pre-charged to the pre-charge voltage VBL by the reading circuit.

When the reading operation is started, the pre-charge enable signal PC being at the power supply voltage VDD is driven to a ground voltage VSS, and a column selection line YS1 being at the ground voltage VSS is driven to a boost potential VDH (for example, 1.5 V or higher), so that the selecting transistors QD1 and QD2 are conducted. At this time, the bit line BL1 is maintained at the pre-charge voltage VBL because it is at an equivalent potential to the common data line I/O, and the source line SL1 is driven to a source voltage VSL (for example, 0.5 V) by the selecting transistor QD1. With respect to the source voltage VSL and the pre-charge voltage VBL, the pre-charge voltage VBL is higher than the source voltage VSL, and their difference is set so as to have a relation that the terminal voltage of the resistor element RM is within a range of the reading voltage region as illustrated in FIG. 12.

Next, when the word line WL1 being at the ground voltage VSS is driven to the boost potential VDH, the memory cell transistors QM of all of memory cells MC connected to the word line WL1 are conducted. At this time, a current path is generated in the memory cell MC11 in which the potential difference is caused in its resistor element RM, and the bit line BL1 and the common data line I/O are discharged toward the source voltage VSL with the speed in accordance with the resistance value of the resistor element RM. As illustrated in FIG. 13, since the case of retaining the memory information “1” is defined to have a smaller resistance value than the case of retaining the memory information “0”, the discharge is faster. Therefore, signal voltage in accordance with the memory information is generated.

Since a potential difference of the resistor element RM of a non-selected memory cell MC12 is 0, a non-selected bit line BL2 is maintained at the pre-charge voltage VBL. More specifically, the reading current is carried via the bit line BL1 to only the memory cell MC11 selected by the word line WL1 and the source line SL1.

Here, if the reading information is already discriminated in the reading circuit RC, the word line WL1 can be fallen. Note that, if the word line WL1 is continued to be risen when the discrimination is slow, the selected bit line BL1 is discharged close to the source voltage VSL even in the case of reading the memory information “0”, and a difference between the signal voltage of reading “0” and the signal voltage of reading “1” is reduced, and therefore, the memory information is not correctly read in some cases. In such a case, by falling the word line WL1 at a timing before the bit line voltage in the case of reading “0” exceeds a reference voltage VDR, error operation can be prevented. Since the signal voltage on the common data line I/O is maintained by falling the word line WL to break the current path, the reading circuit RC can discriminate positive or negative signal generated with taking the reference voltage VDR as reference.

When the above-described reading operation is finished, the common data line I/O is driven to the pre-charge voltage VBL to return back to the stand-by state. Note that, if the bit lines BL1 and BL2 and the source lines SL1 and SL2 are made to be in a floating state in the stand-by state, a capacitance of the bit line BL1 or BL2 whose voltage is unstable is charged from the common data line I/O when the bit line BL1 or BL2 and the common data line I/O are connected at the start of the reading operation. Therefore, in FIG. 13, the column selection line YS1 is also fallen in accordance with the word line WL1, and further, the pre-charge enable signal PC being at the ground voltage VSS is driven to the power supply voltage VDD, whereby the bit line BL1 and the source line SL1 are driven to the pre-charge voltage VBL to be in the stand-by state.

Also, the boost potential VDH is a voltage widely used in a conventional DRAM and is set so as to satisfy a relation of VDH>(VDD+Vth) in which VDD is a power supply voltage and Vth is a threshold voltage of a MIS transistor. For example, in the writing operation to the phase change memory, a larger current flow than that of the reading operation is required as described later. Therefore, in the present invention, the word line WL and the column selection line YS are driven to the boost potential VDH to reduce the resistance of the MIS transistor, whereby a correct writing operation can be performed.

Further, by setting the pre-charge voltage VBL to be higher than the source voltage VSL, the selected source line SL is set to the source region of the memory cell transistor QM in the selected memory cell MC, so that a voltage between the gate and the source of the MIS transistor can be secured regardless of the resistance of the resistor element RM. Note that, even when the potential relation is opposite, if the difference of the potentials is set to be within the range of the reading voltage region as illustrated in FIG. 12, the same selecting operation is possible.

Note that, although FIG. 13 is the example of driving the source line SL1 first, and then, driving the word line WL1, the word line WL1 may be driven first, and then, the source line SL1 may be driven depending on a design reason. In this case, since the word line WL1 is driven first and the selecting transistor QD is conducted, the terminal voltage of the resistor element RM is secured at 0 V. Thereafter, when the source line SL1 is driven, the terminal voltage of the resistor element RM is increased from 0 V, and a value of the voltage can be controlled by a driving speed of the source line SL1 and can be set within the range of the above-described reading voltage region. Similarly, it is also possible to drive the word line WL1 and the source line SL1 almost simultaneously. Also, if the column selection line YS1 is driven prior to a pulse of either one of the word line WL1 or the source line SL1 having a slower driving timing, an output stand-by time to the common data line I/O can be reduced, and therefore, an access time becomes fast. In this case, a connecting wire needs to be changed so as to independently drive each of the selecting transistors QD1 and QD2 illustrated in FIG. 10.

In the foregoing, the example of selecting the memory cell MC11 has been described, but other memory cells (MC21, MC31, and MC41) connected to the same bit line BL1 are not selected because their word line voltages are fixed at the ground voltage VSS. Also, since the other bit line (BL2) and source line SL2 are at the same potential (VBL), the rest of memory cells MC are also maintained in the non-selected state.

In the description above, in order to prevent the operation from being influenced by the current flowing via the non-selected memory cell MC, the word line WL in the stand-by state is set at the ground voltage VSS and the source line SL in the selected state is set at a positive source voltage VSL (for example, 0.5 V). More specifically, by setting the word line voltage in the stand-by state to the ground voltage VSS and setting the source voltage VSL to the positive voltage, the threshold voltage of the memory cell transistor QM can be lowered.

Also, by setting the selected source line SL to the ground voltage 0 V and setting the word line WL in the stand-by state to a negative voltage, the threshold voltage Vth of the memory cell transistor QM can be lowered. In this case, it is required to generate the negative voltage for the word line WL at the stand-by, but since the voltage of the source line SL at the time of selecting becomes the ground voltage VSS applied from outside, the voltage of the source line SL becomes stable. Further, if the threshold voltage Vth of the memory cell transistor QM is set to sufficiently high, the source line SL at the selecting and the word line WL in the stand-by state may be set to the ground voltage 0 V. In this case, since the voltage of the source line SL is the ground voltage VSS applied from outside, and further, the capacitance of the word line WL in the stand-by state functions as a stabilizing capacitor, the voltage of the source line SL can be further stable.

Still further, an operation in which the voltage of the signal read by the common data line I/O is discriminated by the reading circuit RC has been described here, but an operation in which a current of signal flowing in the common data line I/O is discriminated is also possible. In this case, for example, a sense circuit having a small input impedance as described in Patent Document 2 (U.S. Pat. No. 5,883,827) is used as the reading circuit RC. By employing the method of sensing the current like this, influence of the wire capacitance of the common data line I/O becomes small, and therefore, the reading time can be shortened.

FIG. 14 illustrates waveforms explaining the writing operation to the phase change memory element according to the embodiment of the present invention. With reference to FIG. 14, the writing operation to the memory cell MC11 will be described. Note that FIG. 14 illustrates operation waveforms in a case of selecting the memory cell MC11 illustrated in FIG. 10.

First, the selecting operation of the memory cell MC11 is performed in the same manner as the above-described reading operation. When the memory cell MC11 is selected, the writing circuit WC drives the common data line I/O to generate a writing current IWC. In a case of writing “0”, the reset current set to a value in the range illustrated in FIG. 12 is applied to the memory cell MC11. A pulse width of the reset current is short, and it is returned back to the stand-by state right after the driving and its current value becomes 0. By the reset current, the same Joule heat as that of the reset pulse is generated.

On the other hand, in a case of writing “1”, the set current set to a value in the range illustrated in FIG. 12 is applied. The pulse width is about 50 ns. By the set current, the same Joule heat as that of the set pulse is generated. In this manner, the application time of the writing pulse and its current value are controlled by the writing circuit WC, and therefore, the memory cell MC11 is in the selected state only during the pulse width of the set current in the cases of writing any memory information.

(Semiconductor Device Including Phase Change Memory Element and Process for Producing the Same)

First, a configuration of a semiconductor device according to the present embodiment including an array configuration illustrated in FIG. 10 will be described with reference to FIG. 2. A right side of FIG. 2 shows a memory cell region “mmry” and a left side of the same shows a logic circuit region “lgc”.

On a silicon substrate 51 in the logic circuit region lgc, a p-type well 52 and an n-type well 52a are formed. An re-channel MIS transistor QN is formed on the p-type well 52, and a p-channel MIS transistor QP is formed on the n-type well 52a. In the logic circuit region lgc, a logic circuit, a sense amplifier circuit, and the like using these MIS transistors (QN and QP) are formed.

The n-channel MIS transistor QN includes: semiconductor regions (source and drain regions) DN1 and DN2 formed on the p-type well 52 so as to be separated from each other and having an LDD (Lightly Doped Drain) structure; a gate insulating film 54; and a gate electrode GN. The p-channel MIS transistor QP includes: semiconductor regions (source and drain regions) DP1 and DNP2 formed on the n-type well 52a so as to be separated from each other and having the LDD structure; the gate insulating film 54; and a gate electrode GP. The n-channel MIS transistor QN and the p-channel MIS transistor QP are separated from each other by an element isolation region 53a of a shallow-trench embedded type, and a sidewall spacer 58 is formed on a side wall of each of the gate electrodes GN and GP.

On the silicon substrate 51 in the memory cell region mmry, the p-type well 52 is formed. On the p-type well 52, memory cell transistors QM1 and QM2 each configured with an re-channel MIS transistor are formed. The memory cell transistors QM1 and QM2 include: semiconductor regions (source and drain regions) DN3 and DNC, and DN4 and DNC each having the LDD structure; the gate insulating film 54; and the gate electrode GN. Each gate electrode GN of the memory cell transistors QM1 and QM2 configures the word line WL, and the sidewall spacer 58 is formed on a side wall of the gate electrode GN. The two memory cell transistors QM1 and QM2 which are adjacent to each other share either one of the source or drain region (semiconductor region DNC).

Two interlayer insulating films 61a and 61b are formed on the n-channel MIS transistor QN, the p-channel MIS transistor QP, and the memory cell transistors QM1 and QM2 configured as described above, and an upper surface of the interlayer insulating film 61b corresponding to the second layer is flattened so as to have substantially uniform height in the logic circuit region lgc and the memory cell region mmry.

In the interlayer insulating films 61a and 61b in the memory cell region mmry, contact holes are formed so as to expose the semiconductor regions DN3, DN4, and DNC of the memory cell transistors QM1 and QM2. In the contact holes, a conductive barrier film 62 or 64 each formed of, for example, a titanium film and a titanium nitride film and a main conductive film 63 or 65 each made of, for example, tungsten are buried to form contact electrodes. The contact electrodes are electrically connected to the semiconductor regions DN3, DN4, and DNC of the memory-cell selecting MIS transistors QM1 and QM2.

Also, in the interlayer insulating films 61a and 61b in the logic circuit region lgc, contact holes are formed so as to expose an upper surface of the semiconductor region DN1 of the n-channel MIS transistor QN and the semiconductor region DP of the p-channel MIS transistor QP. In the contact holes, a conductive barrier film 64a formed of, for example, a titanium film and a titanium nitride film and a main conductive film 65a made of, for example, tungsten are buried to form contact electrodes. The contact electrodes are electrically connected to the semiconductor region DN of the n-channel MIS transistor QN and the semiconductor region DP of the p-channel MIS transistor QP.

On the interlayer insulating film 61b, an interlayer insulating film 61c is formed. The interlayer insulating film 61c is made of, for example, silicon oxide. In the interlayer insulating film 61c in the logic circuit region lgc, a wire trench is formed so as to expose the contact electrodes configured with the conductive barrier film 64a formed of, for example, a titanium film and a titanium nitride film and the main conductive film 65a made of, for example, tungsten. In the wire trench, a conductive barrier film 66a formed of, for example, a titanium film and a titanium nitride film and a main conductive film 67a made of, for example, tungsten are buried to form a first layer wire M1. The first layer wire M1 is electrically connected to the contact electrodes configured with the conductive barrier film 64a and the main conductive film 65a made of tungsten, and is further electrically connected to the semiconductor region DN of the n-channel MIS transistor QN and the semiconductor region DP of the p-channel MIS transistor QP via the contact electrodes.

Also, in the interlayer insulating film 61c in the memory cell region mmry, a wire trench is formed so as to expose the contact electrode configured with the conductive barrier film 62 formed of, for example, a titanium film and a titanium nitride film and the main conductive film 63 made of, for example, tungsten. In the wire trench, a conductive barrier film 66b formed of, for example, a titanium film and a titanium nitride film and a main conductive film 67b made of, for example, tungsten are buried, so that 66b and 67b form a source line wire SL. The source line wire SL is electrically connected to the contact electrode configured with the conductive barrier film 62 and the main conductive film 63, and is further electrically connected to the semiconductor region DNC shared by the memory-selecting n-channel MIS transistors QM1 and QM2 via the contact electrode.

Further, in the interlayer insulating film 61c in the memory cell region mmry, wire trenches are formed so as to expose the contact electrodes configured with the conductive barrier film 64 formed of, for example, a titanium film and a titanium nitride film and the main conductive film 65 made of, for example, tungsten. In the wire trenches, a conductive barrier film 66 formed of, for example, a titanium film and a titanium nitride film and a main conductive film 67 made of, for example, tungsten are buried, and the conductive barrier film 66 and the main conductive film 67 form a first layer wire pad M1P. The first layer wire pads M1P are electrically connected to the contact electrodes configured with the conductive barrier film 64 and the main conductive film 65 made of tungsten, and are further electrically connected to the semiconductor regions DN3 and DN4 of the memory-cell selecting n-channel MIS transistors QM1 and QM2 via the contact electrodes.

On an upper surface of the interlayer insulating film 61c, an interlayer insulating film 61d is deposited. The interlayer insulating film 61d is made of, for example, silicon oxide. In the interlayer insulating film 61d in the memory cell region mmry, contact holes are formed so as to expose the first layer wire pads M1P configured with the conductive barrier film 66 and the main conductive film 67 made of tungsten. In the contact holes, a conductive barrier film 69 formed of, for example, a titanium film and a titanium nitride film and a main conductive film 70 made of, for example, tungsten are buried to form plugs BEC. The contact electrodes BEC configure bottom electrode contacts of the resistor element RM, and are connected to the semiconductor regions DN3 and DN4 of the memory cell transistors QM1 and QM2 via the first layer wire pads M1P and the plugs therebelow.

On the plug BEC, the interface layer 68, the memory layer 71, and the upper electrode layer 72 of the resistor element RM are formed. The interface layer 68 of the resistor element RM is formed of, for example, a Ta₂O₅ (tantalum oxide) film or a Cr₂O₃ (chromium oxide) film, and it functions as an adhesive layer for preventing the peel between the interlayer insulating film 61d and the memory layer 71. Also, the upper electrode layer 72 of the resistor element RM is formed of, for example, a W film.

Here, when the memory layer 71 of the resistor element RM is formed of a phase change film represented by the following general expression (1), sufficient heat resistance (for 10 years or longer at 85° C. in all elements except for the initial defect) and rewriting property (one hundred thousand times or more) can be obtained.

M_{α}Ge_{X}Sb_{Y}Te_{Z} (1)

Here, α, X, Y, and Z in the expression satisfy 0≦α≦0.4, 0.04≦X≦0.4, 0≦Y≦0.3, 0.3≦Z≦0.6, and 0.03≦(a+Y), respectively. Also, M is at least one element selected from a group of In, Ga, Al, Zn, Cd, Pb, Si, V, Nb, Ta, Cr, Mo, W, Ti, Fe, Co, Ni, Pt, Pd, Y, and Eu. Compared with the element indicated by M and Sb, the phase change film containing the element indicated by M is more preferable because the temperature at which the heat resistance can be guaranteed for 10 years or longer is higher by 5° C. or more.

As described above, when α is larger than 0.4, the multiple-time rewrite of one hundred thousand times or more is difficult. When X is smaller than 0.04, the heat resistance is insufficient, and when X is larger than 0.4, the set pulse width exceeds 100 μs. When Y is larger than 0.3, the heat resistance is insufficient. When Z is out of a range of 0.3 or larger and 0.6 or smaller, the heat resistance is insufficient. When (α+Y) is smaller than or equal to 0.03, the multiple-time rewrite of one hundred thousand times or more is difficult.

Also, it is allowed that a small amount of nitrogen or oxygen is added to the phase change film configuring the memory layer 71. The additive amount in this case is preferably 5 atom % or smaller.

Under the resistor element RM, an etching stopper film 101 is formed. Also, on the resistor element RM, an interlayer insulating film 61g is formed, and an upper surface of the interlayer insulating film 61g is flattened so as to have a substantially uniform height in the logic circuit region lgc and the memory cell region mmry.

In the interlayer insulating film 61g and the etching stopper film 101 in the memory cell region mmry, contact holes are formed so as to expose the upper electrode layers 72 of the resistor elements RM, and in the contact holes, a conductive barrier film 73 formed of, for example, a titanium film and a titanium nitride film and a main conductive film 74 made of, for example, tungsten are buried. The etching stopper film 101 is a protective film for preventing the material configuring the resistor element RM from being etched so as not to deteriorate the characteristic thereof when the interlayer insulating film 61g is etched to form the contact holes. Also, the conductive barrier film 73 and the main conductive film 74 configure the plugs TEC.

Further, in the interlayer insulating film 61g, the etching stopper film 101, and the interlayer insulating film 61d in the logic circuit region lgc, a contact hole is formed so as to expose the first layer wire M1, and in the contact hole, a conductive barrier film 73a formed of, for example, a titanium film and a titanium nitride film and a main conductive film 74a made of, for example, tungsten are buried.

On the interlayer insulating film 61g, a second layer wire configured with a conductive barrier film 75 formed of, for example, a titanium film and a titanium nitride film and a main conductive film 76 made of, for example, tungsten is formed. The second layer wire in the memory cell region mmry configures the bit line BL illustrated in FIGS. 10 and 11 and is connected to the upper electrode layers 72 of the resistor elements RM via the plugs TEC. Also, the second layer wire in the logic circuit region lgc is connected to the first layer wire M1 via the plug therebelow. Note that, although interlayer insulating films are formed also on the second layer wires M2 and BL, the illustrations thereof are omitted.

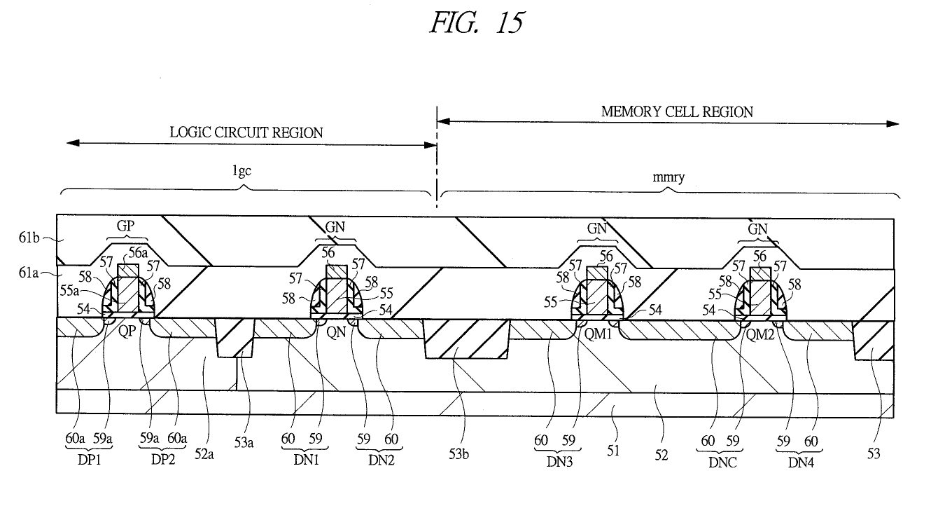

Next, a process for producing the semiconductor device according to the present embodiment illustrated in FIG. 2 will be described in the order of process steps with reference to FIGS. 15 to 24.

First, as illustrated in FIG. 15, for example, a p-type single crystal silicon substrate 51 is prepared, and the p-type well 52, the n-type well 52a, and the element isolation regions 53, 53a, and 53b are formed on a main surface of the substrate with using a well-known method. The p-type well 52 and the n-type well 52a partitioned by the element isolation regions 53, 53a, and 53b become active regions in which elements such as the n-channel MIS transistor QN, the p-channel MIS transistor QP, and the memory cell transistor QM are formed.

Subsequently, on the p-type well 52 in the memory cell region mmry, the memory cell transistors QM1 and QM2 are formed. Also, in the logic circuit region lgc, the n-channel MIS transistor QN is formed on the p-type well 52 and the p-channel MIS transistor QP is formed on the n-type well 52a.

For forming the memory cell transistors QM1 and QM2, the n-channel MIS transistor QN, and the p-channel MIS transistor QP, first, heat treatment and nitriding treatment are performed to each surface of the p-type well 52 and the n-type well 52a to form a gate insulating film 54 formed of a silicon oxynitride film and having a thickness of about 1.5 to 10 nm.

Subsequently, after depositing a polycrystalline silicon film on the silicon substrate 51 by the CVD method, impurities are ion-implanted into the polycrystalline silicon film, whereby a conductive type of a polycrystalline silicon film 55 on the p-type well 52 becomes an n type and a conductive type of a polycrystalline silicon film 55a on the n-type well 52a becomes a p type. Next, by dry-etching the polycrystalline silicon films, a gate electrode GN (word line WL) is formed on the gate insulating film 54 in the memory cell region mmry, and gate electrodes GN and GP are formed on the gate insulating film 54 in the logic circuit region lgc.

Subsequently, n⁻-type semiconductor regions 59 are formed under both side walls of the gate electrode GN by ion-implanting P (phosphorous) to the p-type well 52, and p⁻-type semiconductor regions 59a are formed under both side walls of the gate electrode GP by ion-implanting B (boron) to the n-type well 52a.

Subsequently, after depositing an insulating film on the silicon substrate 51 by the CVD method, the insulating film is dry-etched to form sidewall spacers 58 on side walls of the gate electrodes GN and GP. The insulating film forming the sidewall spacer 58 is a stacked film of, for example, a silicon oxide film and a silicon nitride film.

Subsequently, n⁺-type semiconductor regions 60 are formed under both side walls of the gate electrode GN by ion-implanting P to the p-type well 52, and p⁺-type semiconductor regions 60a are formed under both side walls of the gate electrode GP by ion-implanting B to the n-type well 52a. Note that, after that, a metal silicide layer 56 may be formed on each surface of the gate electrodes GN and GP, and a metal silicide layer (not illustrated) may be formed on each surface of the semiconductor regions DN1, DN2, DN3, DN4, DNC, DP1, and DP2 with using a well-known method.

Subsequently, an interlayer insulating film 61a formed of a silicon oxide film is deposited on the silicon substrate 51 by the CVD method, and then, an interlayer insulating film 61b formed of a silicon oxide film is deposited on the interlayer insulating film 61a by the CVD method. Thereafter, a surface of the interlayer insulating film 61b is flattened by the chemical mechanical polishing (CMP) method.

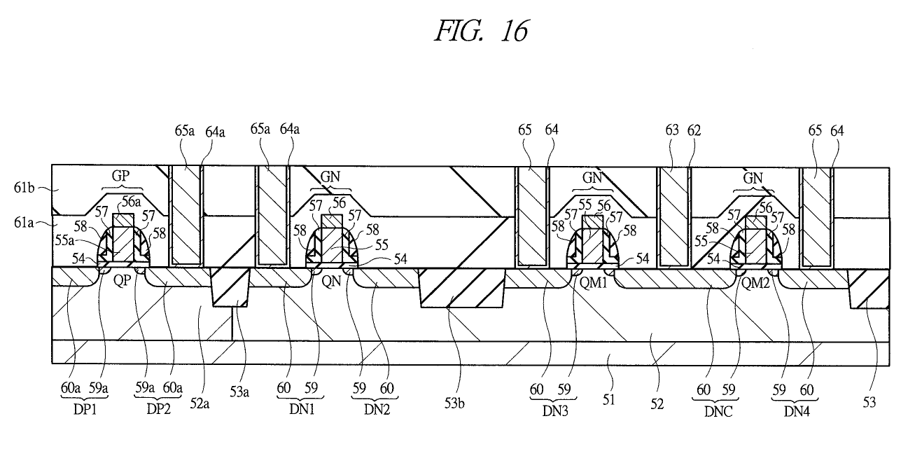

Subsequently, as illustrated in FIG. 16, the interlayer insulating films 61a and 61b are dry-etched with using a photoresist film (not illustrated) as a mask, whereby contact holes are formed so as to expose the respective semiconductor regions DN1, DP2, DN3, DN4, and DNC. Next, in the contact holes, the conductive barrier films 62, 64, and 64a each formed of, for example, a titanium film and a titanium nitride film and the main conductive films 63, 65, and 65a each made of, for example, tungsten are buried with using a well-known method, thereby forming the plugs.

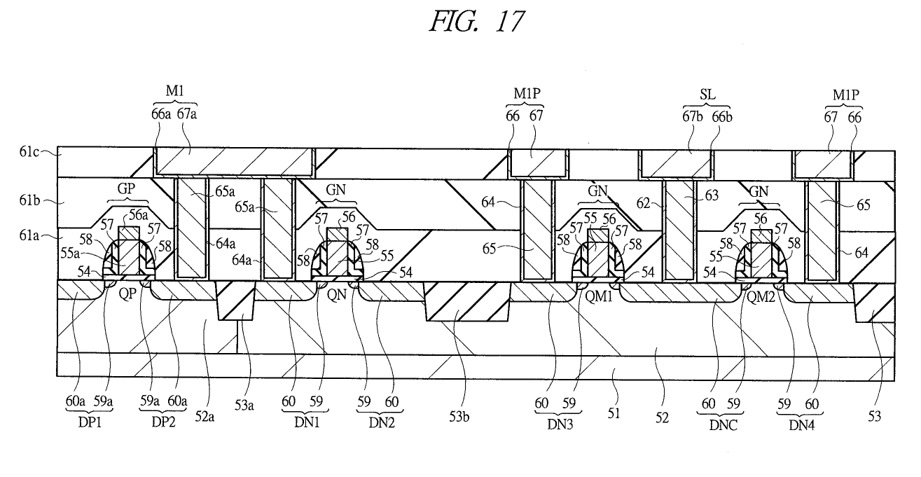

Subsequently, as illustrated in FIG. 17, an interlayer insulating film 61c formed of a silicon oxide film is deposited on the interlayer insulating film 61b by the CVD method, and then, the interlayer insulating film 61c is dry-etched with using a photoresist film (not illustrated) as a mask, whereby wire trenches are formed so as to expose the respective main conductive films 63, 65, and 65a. Thereafter, in the wire trenches, the first layer wires M1, M1P, and SL configured with the conductive barrier film 66, 66a and 66b each made of Ti/TiN and the main conductive film 67, 67a, and 67b each made of W are formed with using a well-known method.

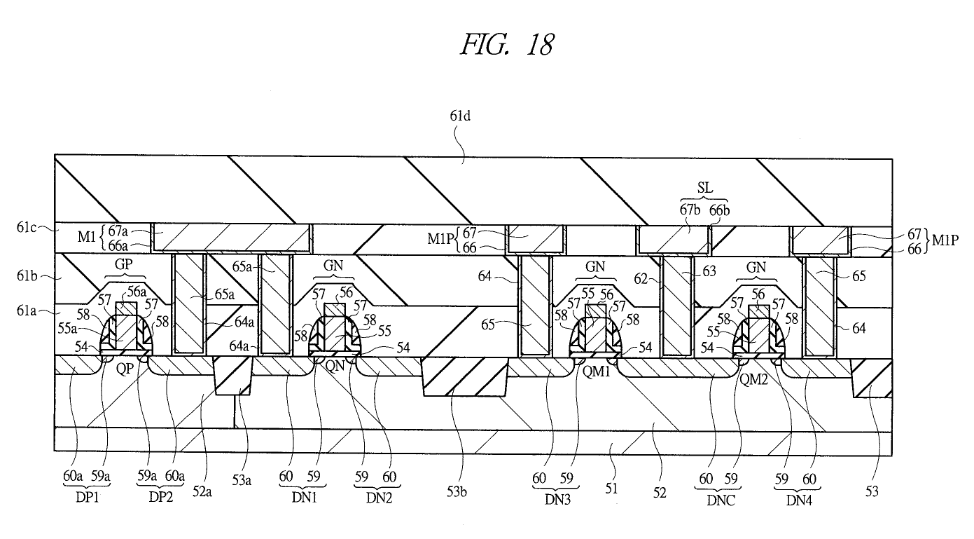

Subsequently, as illustrated in FIG. 18, an interlayer insulating film 61d formed of a silicon oxide film is deposited on the interlayer insulating film 61c by the CVD method.

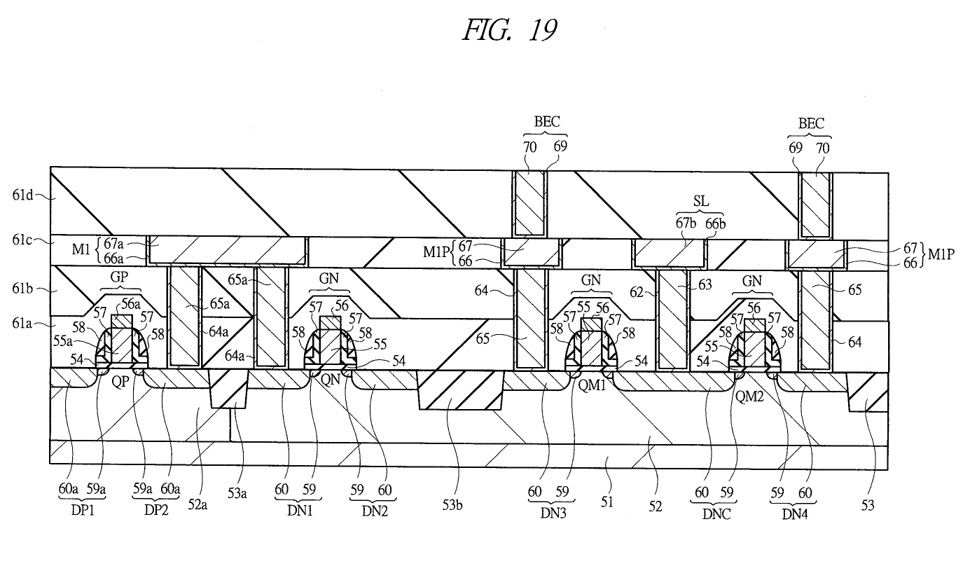

Subsequently, as illustrated in FIG. 19, the interlayer insulating film 61d is dry-etched with using a photoresist film (not illustrated) as a mask, whereby contact holes are formed so as to expose the first layer wires M1P. Thereafter, in the contact holes, the plugs (bottom electrode contact) BEC configured with the conductive barrier film 69 made of Ti/TiN and the main conductive film 70 made of W are formed with using a well-known method. For the plug BEC configuring the bottom electrode contact of the resistor element RM, not only W but also a metal whose surface is easily flattened, for example, Mo (molybdenum) having a small crystal grain size or the like can be used. Since the metal with good flatness has an effect of suppressing the local phase change due to electric field concentration caused in a concavo-convex portion of the surface of the plug BEC, uniformity of electric property, the number of rewritable times, and an operation property such as the high temperature resistance of the memory cell MC can be improved.

Next, as illustrated in FIG. 20, the interface layer 68, the memory layer 71 formed of the phase change material film, and the memory cell upper electrode layer 72 are deposited on the interlayer insulating film 61d in this order from below. A material forming the interface layer 68 is a metal oxide such as tantalum oxide Ta₂O₅ or chromium oxide Cr₂O₃, and its thickness is 0.05 to 5 nm. As a process for forming the interface layer 68, in addition to the generally-used reactive sputtering, a method in which, after metal (tantalum Ta or chromium Cr) is deposited by sputtering, oxidation treatment is performed with oxygen radical can be used.

On the interface layer 68, the memory layer 71 formed of the phase change material film (In—Ge—Sb—Te film) is deposited by the sputtering method using a plurality of targets. The memory layer 71 is configured with the components of the above-described expression (1), and its thickness is, for example, 20 to 200 nm. Note that, for forming the above-described fine structure, that is, for precipitating In being the additive element or InTe being a compound of the additive element in the memory layer 71, it is required to provide thermal energy to the memory layer 71. Although described later, when current is carried as thermal application, the application is preferably performed at the time of inspection for the purpose of the reduction of the number of processes.

Subsequently, the upper electrode layer 72 is deposited on the memory layer 71 by the sputtering method. The upper electrode layer 72 is made of, for example, tungsten, and its thickness is 50 to 200 nm.

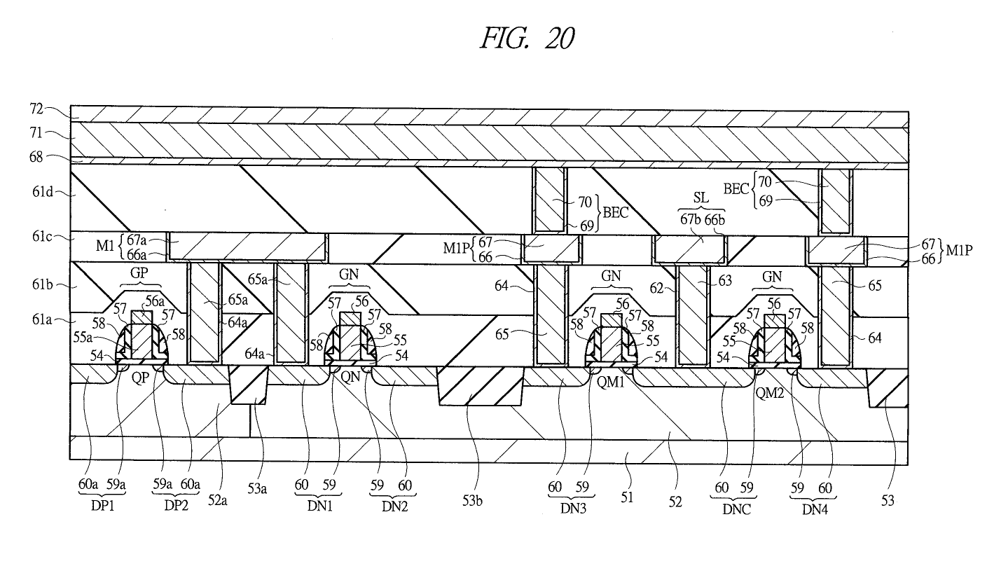

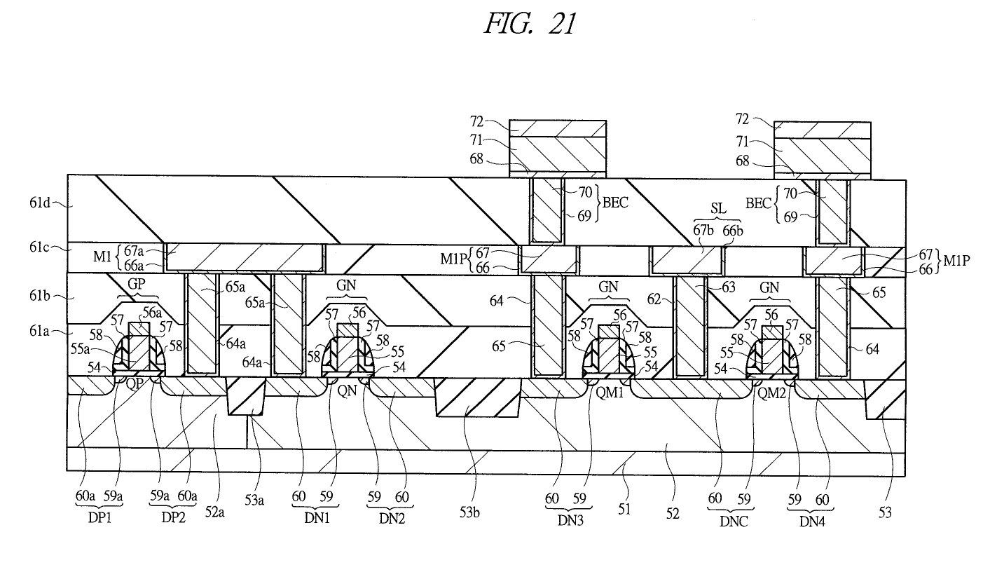

Subsequently, as illustrated in FIG. 21, the upper electrode layer 72 formed of a tungsten film, the memory layer 71, and the interface layer 68 are dry-etched with using a photoresist film as a mask, whereby the resistor elements RM configured with the plug (bottom electrode contact) BEC, the interface layer 68, the memory layer 71, and the upper electrode layer 72 are formed.

Also, although not illustrated, the resistor element RM may be formed with using a hard mask. In this case, a material of the hard mask is, for example, a silicon nitride film. More specifically, a silicon nitride film is deposited on the upper electrode layer 72, and the silicon nitride film is dry-etched with using a photoresist film as a mask, thereby forming the hard mask. Thereafter, the upper electrode layer 72, the memory layer 71 formed of the phase change material film, and the interface layer 68 are dry-etched with using the silicon nitride film as a mask, whereby the resistor elements RM configured with the plug (bottom electrode contact) BEC, the interface layer 68, the memory layer 71, and the upper electrode layer 72 are formed.

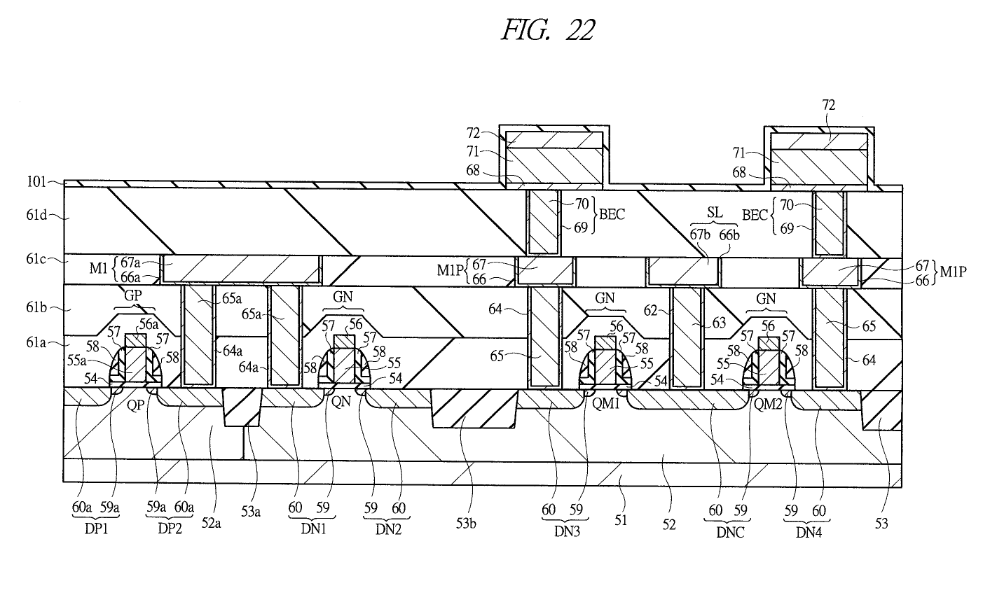

Next, as illustrated in FIG. 22, the etching stopper film 101 formed of a silicon nitride film is deposited on the resistor elements RM by the CVD method. The silicon nitride film of the etching stopper film 101 is desirably deposited at a temperature of 400° C. or lower for preventing sublimation of the memory layer 71 exposed to side walls of the resistor element RM.

Subsequently, as illustrated in FIG. 23, after depositing the interlayer insulating film 61g formed of a silicon oxide film, a surface of the interlayer insulating film 61g is flattened by the CMP method, and the interlayer insulating film 61g and the etching stopper film 101 are dry-etched with using a photoresist film (not illustrated) as a mask, whereby contact holes are formed so as to expose the upper electrode layers 72 of the resistor elements RM.

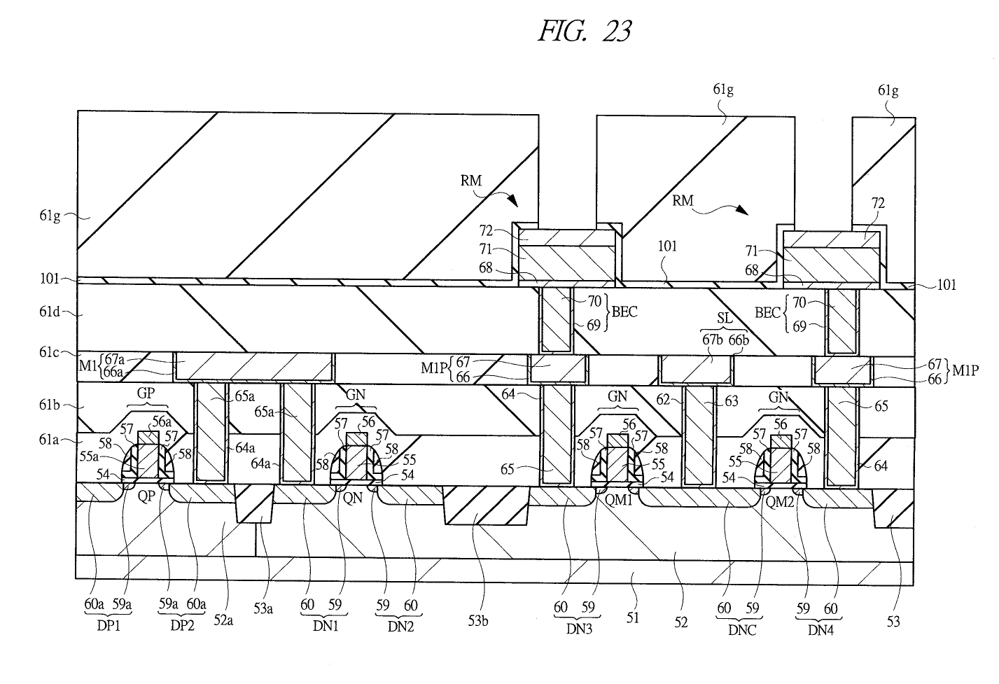

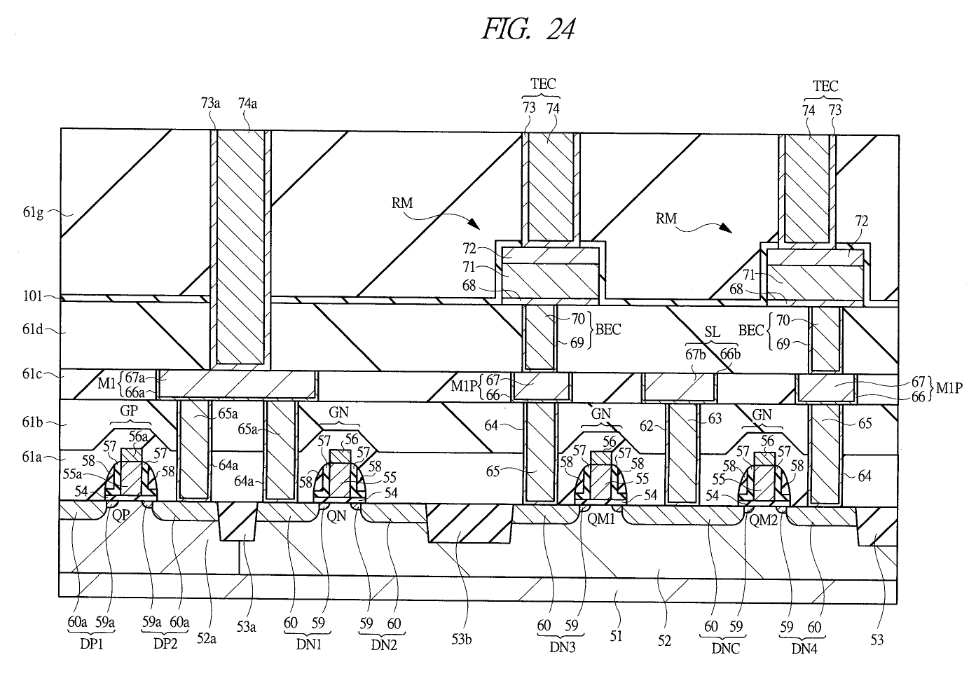

Subsequently, as illustrated in FIG. 24, the interlayer insulating film 61g, the etching stopper film 101, and the interlayer insulating film 61d are dry-etched, whereby a contact hole is formed so as to expose the first layer wire M1. Subsequently, in the contact holes, plugs configured with conductive barrier film 73 or 73a each made of Ti/TiN and a main conductive film 74 or 74a each made of W (tungsten) are formed with using a well-known method.

Thereafter, the conductive barrier film 75 formed of a titanium film and a titanium nitride film is deposited in this order from below on the interlayer insulating film 61g by the sputtering method or the like, and the main conductive films 76 formed of, for example, an aluminum film is stacked by the sputtering method or the like on the conductive barrier film 75, thereby forming a conductive film. Next, the metal film is dry-etched with using a photoresist film (not illustrated) as a mask to form the bit line BL and the second layer wire M2, whereby the semiconductor device illustrated in FIG. 2 is substantially completed.

The result of the transmission electron microscope observation for the phase change memory according to the present embodiment will be described. In conventional phase change memories, binary information is memorized with the low resistance state caused by crystallization of a phase change material (memory layer) and the high resistance state caused by amorphization of the same. However, in the phase change memory according to the present embodiment, even in the low resistance state, crystal grains have not been observed in 50% or more of the region sandwiched by opposed electrodes by the transmission electron microscope observation. In other words, even in the low resistance state, the phase change material has a mixed state of the crystal phase and the amorphous phase. Therefore, even if the phase change memory according to the present embodiment is brought into the high resistance state by using a reset pulse of 1.3 V for 10 ns and is then heated at 180° C. for 3 hours, decrease of the resistance has not appeared though a severalfold increase in resistance has appeared.

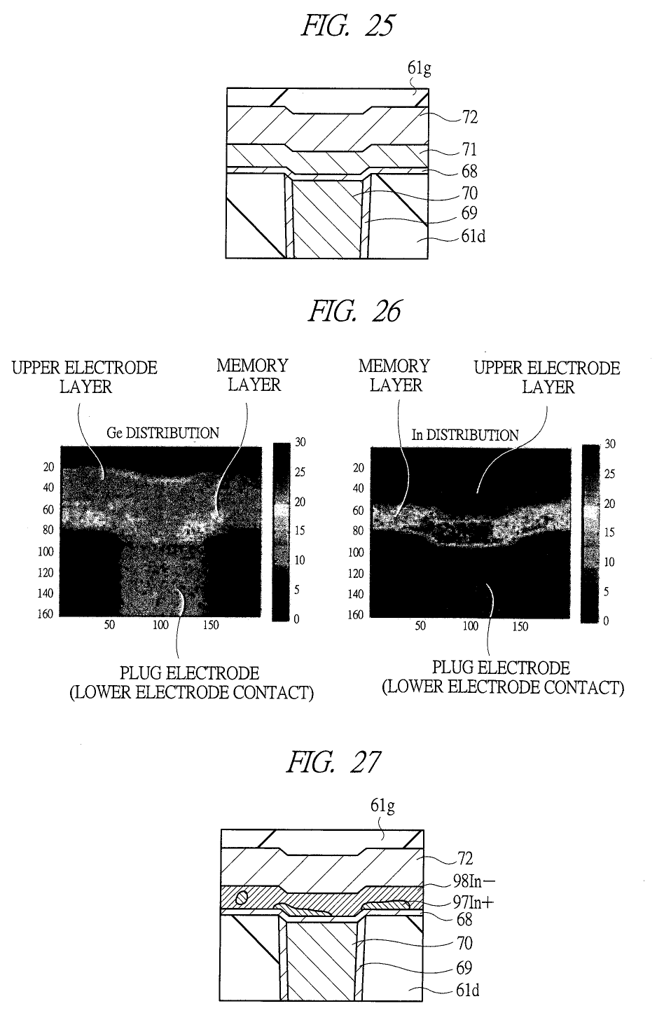

Also, after the initial resistance reduction by sweeping of DC voltage is performed in the phase change memory according to the present embodiment and the phase change memory is rewritten 100 times, the long-term EDX analysis is carried out. The analysis result will be described below. FIG. 25 is an explanatory diagram schematically illustrating a structure of the resistor element RM. FIG. 26 shows a result of the long-term EDX measurement of the resistor element RM after the phase change memory element according to the present embodiment has been rewritten multiple times. FIG. 27 is an explanatory diagram schematically illustrating the result of FIG. 26. Note that structures illustrated in FIGS. 25, 26, and 27 correspond to each other, and the case where the bottom electrode contact BEC of the resistor element RM is a cathode, the upper electrode layer 72 is an anode, and a composition of the phase change material configuring the memory layer 71 is In—Ge—Sb—Te is illustrated.

As illustrated in FIGS. 26 and 27, in the composition of Ge and In, local fine fluctuation and local nonuniformity of an average composition (also referred to as composition ratio) in a region with a size of about 10 nm are observed. It is considered that the nonuniformity like this due to the fine structure having a different composition improves the heat resistance. More particularly, as illustrated in FIG. 27, shading of the In composition ratio in the memory layer 71 is illustrated. It shows that the In concentration differs depending on locations in the memory layer 71 (in FIG. 27, high In concentration region 97 and low In concentration region 98). Further, it also shows that the high In concentration region appears more on the bottom electrode contact BEC side, that is, on the cathode side.

Accordingly, it can be understood that the Ge and In concentrations are higher on the bottom electrode contact BEC side than the upper electrode layer 72 side in the memory layer 71. In other words, it can be understood that Ge and In are more precipitated on the bottom electrode contact BEC side than the upper electrode layer 72 side in the memory layer 71. Also, when precipitated amounts of Ge and In are compared, In is more precipitated on the bottom electrode contact BEC side than the upper electrode layer 72 side in the memory layer 71. This may be because, since In is added to Ge—Te—Sb, In being the additive element or an In compound (InTe) is easily precipitated.

The case where the bottom electrode contact BEC of the resistor element RM is a cathode and the upper electrode layer 72 is an anode has been described above. Alternatively, when the bottom electrode contact BEC is an anode and the upper electrode layer 72 is a cathode, In is more precipitated on the upper electrode layer 72 side than the bottom electrode contact BEC side in the memory layer 71. This is because, since In being the additive element exhibits a positive ion property, In is more precipitated on one electrode (cathode) side than the other electrode (anode) side in the memory layer 71. Also, in FIG. 26, although the case of using In as the additive element has been illustrated, a case of at least one element selected from a group of In, Ga, Al, Zn, Cd, Pb, Si, V, Nb, Ta, Cr, Mo, W, Ti, Fe, Co, Ni, Pt, Pd, Y, and Eu is also the same as the case of In. This is because, since these elements also have a positive ion property, the element is more precipitated on one electrode (cathode) side than the other electrode (anode) side in the memory layer 71.

As described above, it is considered that growth of a crystal formed of M-Ge—Sb—Te under a high temperature environment is suppressed by the additive element or the compound of the additive element precipitated in the memory layer 71. Therefore, the phase change memory element capable of achieving both the high heat resistance and the stable data retention property can be realized.

In the fine structure having a different composition, the set operation becomes difficult when the cycle of the structure and the change in composition ratio are too large, and there arises a problem that a pulse width required for the set operation becomes longer than 1 ms. Therefore, the fine structure having a different composition according to the present embodiment is formed by applying a voltage pulse higher than the rewriting operation voltage by 5% or more and 50% or less, so that change of the set condition is small and is within an actual usable range.

Also, even if the fine structure having a different composition is formed by the heat caused by current, light (ultraviolet, visible, or infrared), or heat conduction at 450° C. or higher and 600° C. or lower and for 10 ns or longer and 10 minutes or shorter, which are higher than the process temperatures of the many processes described above and shorter than the time of the same, the good properties similar to those described above can be obtained.

Further, even if the fine structure having a different composition is formed by the heat caused by current, light (ultraviolet, visible, or infrared), or heat conduction at 90° C. or higher and 150° C. or lower and for 30 minutes or longer and 100 hours or shorter, which are lower than the process temperatures of the many processes described above and longer than the time of the same, the good properties similar to those described above can be obtained.

The current for forming the fine structure is preferably given at the time of inspection for the purpose of the reduction of the number of processes. The laser heating which is one example whose temperature is higher and time is shorter is to be performed after the deposition of the memory layer 71. More specifically, it is desired that the laser is irradiated after the deposition of at least a part of the upper electrode layer 72 for preventing the phase change material from being dispersed and before the patterning of the upper electrode layer 72 for the uniform heating.

In the foregoing, the invention made by the inventors has been concretely described based on the embodiment. However, it is needless to say that the present invention is not limited to the foregoing embodiment and various modifications can be made within the scope of the present invention.

For example, although the case where a Ge—Te—Sb based chalcogenide material (phase change material) is employed for a memory layer of a phase change memory element has been described in the embodiment, other chalcogenide material may be employed.

### INDUSTRIAL APPLICABILITY

A semiconductor device of the present invention can be widely used for a phase change memory (nonvolatile memory) using a phase change material, a memory-embedded logic in which a phase change memory (nonvolatile memory) circuit and a logic circuit are formed on the same semiconductor chip, and the like, and the semiconductor device is more useful when such a product is used under the high temperature condition.

1. A semiconductor device comprising a memory element,
the memory element including:
a memory layer made of M-Ge—Sb—Te in which M is at least one element selected from a group of In, Ga, Al, Zn, Cd, Pb, Si, V, Nb, Ta, Cr, Mo, W, Ti, Fe, Co, Ni, Pt, Pd, Y, and Eu; and
paired electrodes sandwiching the memory layer therebetween, wherein
the memory layer is brought into a high resistance state and a low resistance state by phase change, and the memory element memorizes theses states, and
the element or a compound of the element is precipitated in the memory layer.

2. The semiconductor device according to claim 1, wherein
the element or the compound of the element is amorphous, and
amorphouses each having a different composition are mixed in the memory layer in the high resistance state.

3. The semiconductor device according to claim 1, wherein
crystal and amorphous are mixed in the memory layer in the low resistance state.

4. The semiconductor device according to claim 1, wherein
crystal and amorphous are mixed in the memory layer in the low resistance state, and
the crystal has a composition closer to Ge₂Sb₂Te₅ than the amorphous.

5. The semiconductor device according to claim 1, wherein
a crystal grain size of the memory layer in the low resistance state is smaller than that of Ge₂Sb₂Te₅.

6. The semiconductor device according to claim 1, wherein
a crystal grain size of the memory layer is smaller than a shortest distance between the paired electrodes.

7. The semiconductor device according to claim 1, wherein,
when a composition ratio of the element M in the memory layer is α,
a composition ratio of the Ge in the memory layer is X,
a composition ratio of the Sb in the memory layer is Y, and
a composition ratio of the Te in the memory layer is Z,
an average composition of the memory layer satisfies relations of
0≦α≦0.4,
0.04≦X≦0.4,
0≦Y≦0.3,
0.3≦Z≦0.6, and
0.03≦(α+Y).

8. The semiconductor device according to claim 7, wherein
a relation of 0.03≦α≦0.4 is satisfied.

9. A semiconductor device comprising a memory element,
the memory element including:
a memory layer made of In—Ge—Sb—Te; and
paired electrodes sandwiching the memory layer therebetween, wherein
the memory layer is brought into a high resistance state and a low resistance state by phase change, and the memory element memorizes theses states, and
the In or a compound of the In is precipitated in the memory layer.

10. The semiconductor device according to claim 9, wherein
the compound of the In is InTe.

11. The semiconductor device according to claim 9, wherein
the In or the compound of the In is precipitated between crystals of the In—Ge—Sb—Te.

12. The semiconductor device according to claim 9, wherein
the memory layer contains the In of 10.5 atom % or more.

13. A semiconductor device comprising a memory element,
the memory element including:
a memory layer made of M-Ge—Sb—Te in which M is at least one element selected from a group of In, Ga, Al, Zn, Cd, Pb, Si, V, Nb, Ta, Cr, Mo, W, Ti, Fe, Co, Ni, Pt, Pd, Y, and Eu; and
paired electrodes sandwiching the memory layer therebetween, wherein
the memory layer is brought into a high resistance state and a low resistance state by phase change, and the memory element memorizes theses states, and
a concentration of the element in the memory layer is higher on one electrode side of the paired electrodes than the other electrode side.

14. A semiconductor device comprising a memory element,
the memory element including:
a memory layer made of In—Ge—Sb—Te; and
paired electrodes sandwiching the memory layer therebetween, wherein
the memory layer is brought into a high resistance state and a low resistance state by phase change, and the memory element memorizes theses states, and
a concentration of the In in the memory layer is higher on one electrode side of the paired electrodes than the other electrode side.

15. The semiconductor device according to claim 14, wherein
the memory layer contains the In of 10.5 atom % or more.

16. A process for producing a semiconductor device comprising a memory element,
the memory element including:
a memory layer made of In—Ge—Sb—Te; and
paired electrodes sandwiching the memory layer therebetween, wherein
the memory layer is brought into a high resistance state and a low resistance state by phase change, and the memory element memorizes theses states,
after forming the In—Ge—Sb—Te by a sputtering method, thermal energy is provided to the In—Ge—Sb—Te, whereby the In or a compound of the In is precipitated in the memory layer.

17. The process for producing the semiconductor device according to claim 16, wherein
the thermal energy is generated by a voltage pulse of 5% or higher and 50% or lower of a rewriting operation voltage of the memory element.

18. The process for producing the semiconductor device according to claim 16, wherein
the thermal energy is generated by heat caused by current, light, or heat conduction at 450° C. or higher and 600° C. or lower and for 10 ns or longer and 10 minutes or shorter.

19. The process for producing the semiconductor device according to claim 16, wherein
the thermal energy is generated by heat caused by current, light, or heat conduction at 90° C. or higher and 150° C. or lower and for 30 minutes or longer and 100 hours or shorter.
